(19) United States
(12) Patent Application Publication
(10) Pub. No.: US 2005/0126487 A1
(43) Pub. Date: Jun. 16, 2005

(54) Surface treatment apparatus

(76) Inventors: Toshihiro Tabuchi, Kanagawa-ken (JP); Kouichi Ishida, Kanagawa-ken (JP); Hiroyuki Mizukami, Kanagawa-ken (JP); Masayuki Takashiri, Kanagawa-ken (JP)

Correspondence Address: EVEREST INTELLECTUAL PROPERTY LAW GROUP, P. O. BOX 708, NORTHBROOK, IL, 60065, US

(21) Appl. No.: 11/046,273

(22) Filed: Jan. 28, 2005

Related U.S. Application Data
(62) Division of application No. 09/730,813, filed on Dec. 6, 2000.

(30) Foreign Application Priority Data
Dec. 7, 1999 (JP) 11-347108
Feb. 16, 2000 (JP) 2000-37482
Mar. 10, 2000 (JP) 2000-66106

(51) Int. Cl. C23C 16/00

(52) U.S. Cl. 118/723 E

(57) ABSTRACT

The present invention provides a surface treatment apparatus which can treat a surface with high speed and high quality. A casing of a surface treatment apparatus is defined into two chambers, a plasma generation chamber provided with a plasma generation electrode and a substrate treatment chamber provided with a substrate support table. A plasma nozzle is formed on an anode electrode constituting a partition wall of the both chambers. A recess is formed on an upper cathode electrode. Further, the plasma nozzle is used as a hollow anode discharge generation area, and the recess as a hollow cathode discharge generation area.

### BACKGROUND OF THE INVENTION

1. Field of the Invention

The present invention relates to various surface treatments to a substrate and, especially to a surface treatment apparatus appropriate for forming a film on a substrate, and more particularly to a surface treatment apparatus for forming a crystalline thin film of high quality at a high speed.

2. Description of the Related Art

Conventionally, a surface treatment apparatus for etching, film forming or performing other surface treatments by putting reactive gas into a plasma state by applying high frequency electric power to a parallel plate electrode and decomposing into chemically active ion or radical is publicly known.

For example, in a conventional parallel flat plate type plasma CVD (Chemical Vapor Deposition) apparatus for film formation processing, a pair of flat plate form plasma generation electrodes are installed opposed in parallel in a casing. One of the plasma generation electrodes functions also as a substrate support table and moreover, the apparatus is provided with a heater to adjust a substrate temperature to a temperature appropriate for vapor growth. If an electric power is applied between the both plasma generation electrodes by a high frequency power supply (power source of 13.56 MHz) with a substrate placed on the one electrode, plasma is generated between these electrodes, the raw material gas, for example monosilane gas, is activated to form a silicone film on the substrate surface.

Such conventional parallel flat plate type plasma CVD apparatus has advantage of being able to form a film on a substrate of large area by a single film forming process, by enlarging the area of the flat plate type plasma generation electrode where the substrate is placed. However, in the conventional parallel flat plate type plasma CVD apparatus, the raw material gas made plasma by both the plasma generation electrodes is dispersed uniformly in a film formation gas processing chamber, and only a portion thereof contributes to the film formation on the substrate disposed on the electrode. Therefore, the raw material use efficiency is low and, for example, if an amorphous silicone thin film or a fine crystalline silicone thin film is to be formed on the substrate, the film formation speed is late as about 1 to 2 Å/sec despite a high input electric power. As the consequence, it takes much more time to manufacture a semiconductor device relatively large in thickness such as a solar cell, resulting in low throughput and high costs.

Therefore, in order to increase the film formation speed, it is proposed to increase the input electric power by the high frequency power source. However, the increase of input electric power implies energy increase of charged particles in the plasma. The film quality of the substrate is deteriorated by the damage due to collision to highly energized charged particles with the substrate. Moreover, according to the increase of high frequency power by the high frequency power supply, a quantity of fine particles are generated in the vapor phase, and the film quality will be deteriorated considerably by the fine particles.

Consequently, in the conventional parallel flat plate type plasma CVD apparatus, the input electric power should be limited in order to avoid the film quality deterioration due to damage by high energy charged particles or fine particles. In other words, there is substantially an upper limit of input electric power, and it has been impossible to increase the film formation speed more than a certain level.

Also, in the parallel flat plate type plasma CVD etching apparatus, it is possible to increase the treatment speed for some extent by increasing the input electric power, because the deterioration of treatment quality by the increase of the input electric power is relatively low compared to the film formation processing. However, actually, a further speed-up of treatment is desired, in view of etching treatment quality improvement, manufacturing efficiency improvement or reduction of manufacturing cost.

On the other hand, the formation apparatus of photoelectromotive device on a band shape member, which is a running element to be treated, disclosed in Japanese Patent Laid-Open Publication No. 11-145492, the cathode electrode potential during glow discharge generation is kept positive of +30V or more in respect to the earthed anode electrode including the band shaped member, by making the surface area in the discharge space of the high frequency power impression electrode (cathode electrode) larger than the surface area in the discharge space of whole the anode electrode including the band shaped member. Moreover, a plurality of divider shaped electrodes orthogonal to the running direction of the band shaped member are disposed on the cathode electrode to generate discharge between adjacent divider shaped electrodes also. Thus, the material gas excitation and decomposition reaction are accelerated at the anode electrode side including band shaped member, by keeping the cathode electrode positive of +30V or more in respect to the band shaped member and the anode electrode and, at the same time, composing such a cathode electrode structure including divider shaped electrodes as mentioned above.

It can be admitted that the formation apparatus of the photoelectromotive device disclosed in the foregoing publication is supposed to improve the film formation speed, by accelerating the material gas excitation and decomposition reaction at the anode electrode side including the band shaped member. However, damage due to the charged particle collision persists, because the glow discharge is still generated in the space between the band shaped member and the cathode electrode.

Therefore, in the thin film formation apparatus disclosed, for example, in Japanese Patent Laid-Open Publication No. 61-32417, an activated gas generator comprising a division chamber having a pair of opposed plasma generation electrodes is disposed in a vacuum chamber for forming a thin film on the substrate. A single narrow port is formed on one wall section of the activated gas generator for spouting out activated gas into the vacuum chamber. In addition, the substrate is supported in the vacuum chamber at a position opposed to the narrow port.

In the thin film formation apparatus, plasma is produced by applying high frequency power to the pair of plasma generation electrodes and generating glow discharge between both electrodes. Raw material gas introduced in the activated gas generator is decomposed by this plasma. At this moment, activated raw material gas spouts out from the narrow port towards the substrate, by reducing the vacuum degree of the vacuum chamber lower than the activated gas generator by 2 to 3 places to the right through the adjustment of the vacuum pump disposed in the vacuum chamber and the conductance of the narrow port.

Thus, the film formation speed can be increased without increasing the input electric power in the thin film formation apparatus wherein plasma generation electrodes are disposed in the activated gas generator defined in the vacuum chamber for thin film formation and raw material gas activated in the activated gas generator is actively jetted towards the substrate. Moreover, even when a stronger plasma is generated by increasing the input electric power, as the plasma generation electrodes are disposed in the defined activated gas generator, the glow discharge between both electrodes have no chance to damage the substrate. Therefore, it is possible to increase further the film formation speed by increasing the input electric power. In addition, high quality thin film can be formed faster than before, as the thin film crystallization is accelerated, despite the film formation speed-up.

Thus, the film formation speed has certainly been increased by dividing the plasma generation chamber and the film formation processing chamber; however further increase of film formation speed is desired, and especially, a high speed formation of fine crystalline thin film for the application of solar cell or the like is strongly expected.

### SUMMARY OF THE INVENTION

In order to achieve such expectation, the present invention has an object to provide a surface treatment apparatus that can treat a surface with high speed and high quality.

To solve such problem, a first aspect of the present invention provides a surface treatment apparatus for making raw material gas plasma by generating plasma, in a casing provided with plasma generation means, a raw material gas inlet and a substrate support table, by the plasma generation means and giving plasma treatment the surface of a substrate placed on the substrate support table, wherein the casing is defined into two chambers, plasma generation chamber provided with the plasma generation means and a substrate treatment chamber provided with the substrate support table, the substrate treatment chamber and the plasma generation chamber are connected through one or more plasma nozzles, and a hollow discharge generation area is made in at least a portion of the hollow inside.

Further, a second aspect of the present invention provides a surface treatment apparatus for making raw material gas plasma by generating plasma, in a casing provided with plasma generation means, a raw material gas inlet and a substrate support table, by the plasma generation means and giving plasma treatment to the surface of a substrate placed on the substrate support table, wherein the casing is defined into two chambers, plasma generation chamber provided with the plasma generation means and substrate treatment chamber provided with the substrate support table, the substrate treatment chamber and the plasma generation chamber are connected through one or more plasma nozzles and a hollow plasma generation electrode including one or more hollow discharge generation areas is disposed in the plasma generation chamber.

In addition, a third aspect of the present invention provides a surface treatment apparatus for making raw material gas plasma by generating plasma, in a casing provided with plasma generation means, a raw material gas inlet and a substrate support table, by the plasma generation means and giving plasma treatment to the surface of a substrate placed on the substrate support table, wherein the casing is defined into two chambers, plasma generation chamber provided with the plasma generation means and a substrate treatment chamber provided with the substrate support table, the substrate treatment chamber and the plasma generation chamber are connected through one or more plasma nozzles, at least one of the plasma nozzles is made a hollow discharge generation area and a hollow plasma generation electrode including one or more hollow discharge generation areas is disposed in the plasma generation chamber.

Note that, in the present invention, the hollow discharge means the phenomenon of plasma density increase due to enhanced plasma generation observed especially in through hole, recess or cavity portions.

As plasma generation means, means of discharge by a pair of plasma generation electrodes comprising a cathode and an anode, discharge having electrodes of three poles or more, microwave discharge, capacitance coupling type discharge, inductive coupling type discharge, helicon wave discharge, PIG discharge, electron beam excitation discharge or others can be adopted.

The plasma nozzle is formed in the partition wall between the substrate treatment chamber and a plasma generation chamber. According to the first and third aspects of the invention, the hollow discharge generated at this plasma nozzle becomes hollow cathode discharge or hollow anode discharge by the potential of the plasma nozzle.

For example, when a pair of plasma generation electrodes comprising a cathode and an anode are adopted as the plasma generation means, either one of these electrodes may be used as the partition wall. When the anode electrode is used as the partition wall and the plasma nozzle is formed on the anode electrode, the hollow discharge becomes hollow anode glow discharge. When the cathode electrode is used as the partition wall and the plasma nozzle is formed in the cathode electrode, the hollow discharge becomes hollow cathode glow discharge. Note that, in the present invention, the electrode of the side of the discharge for applying main electric power serves as “cathode electrode” and the electrode opposite to the cathode electrode serves as “anode electrode”. Instead, a partition wall defining two chambers may be disposed separately from a pair of plasma generation electrodes which are plasma generation means, to form a plasma nozzle on that partition wall.

According to the second and third aspects of the invention, when a pair of plasma generation electrodes comprising a cathode and an anode are adopted as the plasma generation means, at least one of the plasma generation electrodes can be used also as the hollow plasma generation electrode. Instead, the hollow plasma generation electrode can be arranged as the third electrode separately from the plasma generation electrodes.

For performing the surface treatment with the aforementioned surface treatment apparatus, first, raw material gas and carrier gas are injected into the casing through a gas supply pipe and plasma is generated in the plasma generation chamber by the plasma generation means. At this moment, as the surface treatment apparatus of the present invention is divided into the plasma generation chamber and the substrate treatment chamber, carrier gas and raw material gas can be used efficiently, and carrier gas and raw material gas plasmatization can be accelerated.

Plasma generated in the plasma generation chamber flows out from the plasma nozzle to the substrate treatment chamber due to the inner gas flow by the exhaust from the substrate treatment chamber or the differential in pressure between two chambers, or due to the dispersion. At this time, the plasma in the plasma generation chamber is transported smoothly from the plasma nozzle into the substrate treatment chamber by providing proper gas flow rate, gas pressure, and plasma parameter.

The raw material gas can also be introduced in the course while plasma generated in the plasma generation chamber flows out from the plasma nozzle and reaches at the substrate surface. The activated raw material gas in plasma reaches at the substrate surface in the treatment chamber through the plasma flow, and etching, film formation or other surface treatment are applied to the substrate.

According to the first aspect of the invention, it is important to generate hollow discharge on at least one of the plasma nozzles. As new plasma is generated at the plasma nozzle by this hollow discharge, the density of plasma directed to the substrate treatment chamber is increased. Further, as for plasma generated in the plasma generation chamber, the energy of charged particles (electron or ion) in the plasma decreases by interactions such as collision, when it passes through the plasma nozzle where hollow discharge occurs. Through the electron energy drop, electrons will have an appropriate energy intensity, strong enough to generate neutral active species contributing to the surface treatment from raw material gas, and moderated not to generate often ions damaging the substrate surface by collision, resulting in increase of neutral active species without increasing the ions. Moreover, the impact of substrate damage due to these ions can be limited by reducing the number of high energy ions in the plasma.

Thus, the surface treatment can be accelerated, because the neutral active species contributing to the surface treatment increase by the plasma density elevation due to the hollow discharge. Moreover, substrate surface deterioration can be controlled and high quality surface treatment can be performed at a high speed, by decreasing the energy of ions existing in the plasma and damaging the substrate by collision.

According to the second aspect of the invention, it is important to arrange hollow plasma generation electrodes in the plasma generation chamber. For instance, when a pair of plasma generation electrodes comprising a cathode and an anode are adopted as the plasma generation means, at least one of these electrodes may be used as hollow plasma generation electrode. Namely, it is required that hollow anode discharge occurs at the anode electrode, or hollow cathode discharge occurs at the cathode electrode, or hollow discharge occurs at both electrodes respectively. The generation of the hollow discharge creates new plasma in that hollow discharge generation area, condensing plasma directed to the substrate treatment chamber, increasing neutral active species contributing to the surface treatment, and further accelerating the surface treatment speed.

Further, according to the third aspect of the invention, both hollow discharge at the plasma nozzle and hollow discharge at the hollow plasma generation electrode mentioned above are generated. Consequently, the aforementioned respective functional effects of both the hollow discharge at the plasma nozzle and the hollow discharge at the hollow plasma generation electrode are provided, further increasing the surface treatment speed and quality.

Moreover, not only the hollow discharge at the plasma nozzle but also the hollow discharge at the hollow plasma generation electrode being generated, in addition to the aforementioned respective functional effects, the following synergistic functional effects can also be obtained. Namely, not only hollow discharge at the plasma nozzle but also the hollow discharge at the hollow plasma generation electrode being generated, the electron temperature lowers in the hollow discharge area of the electrode and, at the same time, the electron density increases, resulting in improvement of performance as process plasma. And further, when the cathode electrode is the hollow plasma generation electrode and hollow discharge occurs at the cathode electrode, the space potential of plasma generated in the plasma generation chamber increases, as the high frequency voltage at the cathode electrode decreases and, at the same time, self-bias voltage increased. As a result, hollow discharge occurs easily at the plasma nozzle, making it possible to generate high density plasma at the plasma nozzle. Moreover, the electric field concentration occurs more easily in the plasma generation chamber for the same reason and an uneven discharge of locally high density plasma can be generated.

As electrode material of the hollow plasma generation electrode, and as electrode material when a pair of plasma generation electrodes are used as plasma generation means, besides SUS or Al, Ni, Si, Mo, W or the like can be adopted. When an electrode material presenting a high secondary ion discharge coefficient due to ion impact from plasma, the treatment speed will be increased because plasma density increases further. Moreover, especially in case of a surface treatment apparatus performing silicone film formation, the use of Si as electrode material increases the film formation speed and its stability, because this electrode itself functions as supply source of the film material. Moreover, if an electrode made of Si is previously doped with boron or phosphor, the thin film can be doped automatically, and it is particularly advantageous for doping a trace.

As the substrate, glass, organic film, SUS or other metals can be used. Further, the surface treatment apparatus of the present invention can be used for various surface treatments such as film formation, ashing, etching, ion doping, and further it can particularly preferably used for formation of silicone thin film such as crystalline silicone or oxide film.

When a number of the plasma nozzle are to be disposed, hollow discharge generated at all of these nozzles is preferable, as it allows to form an uniform thin film at a high speed even for a large area substrate.

The raw material gas inlet may be opened in the plasma generation chamber, or, only carrier gas may be introduced in the plasma generation chamber, and the raw material gas inlet can be provided at the side face of the plasma nozzle. Moreover, the raw material gas inlet can be opened by using, for example, a raw material gas introduction pipe, to introduce the raw material gas between the plasma nozzle and the substrate in the substrate treatment chamber. When the raw material gas inlet is opened at the plasma nozzle or in the substrate treatment chamber, the raw material gas is plasmatized by plasmatized carrier gas passing through the nozzle. In this case, the inner wall surface of the plasma generation chamber will not be contaminated with the raw material gas.

The plasma generation electrode can be applied to direct current to high frequency power by connecting to a direct current source or high frequency source, but especially, it is preferable to input high frequency power. Further, bias can be applied to the cathode electrode and the anode electrode respectively by a DC power supply, AC power supply or pulse generation power supply.

In order to generate hollow discharge at the plasma nozzle, preferably, an opening width W(1) of the smallest portion on at least one of the plasma nozzles is set in a range satisfying either of W(1)≦5L(e) or W(1)≦20X. L(e) is an electron mean free path in respect to atom or molecular species (active species) of the smallest diameter among raw material gas species and electrically neutral atom or molecular species (active species) produced therefrom by decomposition, under the desired plasma generation conditions. And X is a thickness of a sheath layer generated under the desired plasma generation conditions. In addition, it is preferable to set the opening width W(1) of the smallest portion on at least one of the plasma nozzles in a range satisfying either X/20≦W(1) and X/5≦W(1).

The electron mean free path in respect to the atom in the dispersion with electron and gas molecular (including atom) depends on gas pressure, atom and molecular dispersion cross section area and temperature, and the plasma generation conditions include these gas pressure, atom and molecular dispersion cross section area, temperature and the like.

Hollow glow discharge can be generated efficiently at the plasma nozzle, and at the time, plasma can be spouted out efficiently from the nozzle, by setting the opening width W(1) of the plasma nozzle in the range mentioned above.

In the present invention, the opening width W(1) of the plasma nozzle corresponds to its diameter when the opening shape of the plasma nozzle is circular, and it corresponds to its short side length dimension when it is rectangular or slit formed. That is, the shortest dimension portion of this opening shape is taken as the opening width W(1).

A shape that can intake plasma of the plasma generation chamber positively into the nozzle, and diffuse and spout plasma in the substrate treatment chamber at a desired angle may be adopted as the shape of the plasma nozzle. Such shape includes cylindrical form having a circular cross-section, truncated cone increasing the diameter from the plasma generation chamber to the substrate treatment chamber, and combination thereof, and further a shape whose diameter of downstream side half increases downwards. And moreover, it may be a prism having a rectangular cross-section or a slit form as mentioned above.

Also, a plurality of the plasma nozzle having circular shape, for example, can be formed in the required pattern, when a large surface area of the substrate is to be given the surface treatment.

Further, preferably, the plasma nozzle forms a substantially continuous and elongated slit shape that can be drawn with a single stroke of the brush.

Here, a substantially continuous slit shape means, when plasma is generated by hollow discharge as mentioned below at the plasma nozzle, a slit shape that would allow this plasma to continue without dividing at one plasma nozzle. For instance, when a rib is formed traversal to the slit of the plasma nozzle, the plasma nozzle is considered substantially continuous, if slit depth direction dimension or width dimension of that rib are sufficiently small so that plasma can override the rib and continue without being divided at the slit shaped plasma nozzle.

Thus, by forming the plasma nozzle as a substantially continuous and elongated slit shape that can be drawn with a single stroke of the brush, plasma is generated by hollow discharge at the plasma nozzle. This hollow discharge becomes hollow cathode glow discharge or hollow anode glow discharge depending on the potential of the plasma nozzle.

Further, it becomes possible to treat the surface over a large area of the substrate by a single treatment, as the plasma nozzle is elongated slit shaped, in other words, the plasma nozzle opens for an area larger than the conventional case where a single nozzle is disposed at the partition wall center.

Preferably, the plasma nozzle is, as sixth to eighth aspects of the invention, whorl shaped, meandering shaped, connected straight line shaped or the like.

Further preferably, the plasma nozzle is formed symmetrically in respect with its center, by which the substrate surface can be treated more evenly.

Further, in order to generate hollow discharge more effectively at the plasma nozzle and, at the same time, to spout out plasma effectively from the plasma nozzle, preferably, the slit width W of the plasma nozzle is set in a range satisfying either of W≦5L (e) or W≦20X. L(e) is an electron mean free path in respect to atom or molecular species (active species) of the smallest diameter among raw material gas species and electrically neutral atom or molecular species (active species) produced there from by decomposition, under the desired plasma generation conditions and X is a thickness of a sheath layer generated under the desired plasma generation conditions.

Preferably, the plasma nozzle varies its slit width from the center to the outer circumference thereof.

Also preferably, the plasma nozzle varies its slit width from the center to the outer circumference thereof.

In the aforementioned surface treatment apparatus, when a pair of plasma generation electrodes is adopted as plasma generation means, the plasma density of hollow discharge generated at the plasma nozzle may vary by the high frequency power applied to the electrodes according to the distance from the nozzle center. In such a case, it can be controlled so that plasma is generated with an uniform density over the total length of the plasma nozzle, for example, by changing the dimension of the slit width or the partition plate thickness, from the center to the periphery of the partition plate, so that the slit width reduces or the partition plate thickness increases to increase the slit depth increases where hollow discharge occurs easily, or on the contrary, the slit width increases or the partition plate thickness decreases where hollow discharge occurs hardly. This allows to treat all over the substrate surface uniformly.

Preferably, the hollow plasma generation electrode includes one or more recesses on a surface opposed to the plasma generated by the plasma generation means and, at least one of the recesses is made the hollow discharge generation are.

Also preferably, the hollow plasma generation electrode is a hollow body, the electrode includes one or more through holes communicating with a hollow inside on a portion opposed to plasma generated by the plasma generation means and, at least one of the through holes is made the hollow discharge generation area.

Thus, the surface area of the hollow plasma generation electrode substantially in contact with plasma increases by forming recesses on the hollow plasma generation electrode, or by making the hollow plasma generation electrode a hollow body and forming through holes communicating with this hollow inside. For example, when the cathode electrode is used as hollow plasma generation electrode and the cathode discharge area is formed on the cathode electrode, the cathode electrode potential (self bias) during the glow discharge generation can be brought to the plus direction, and input electric power consumption in the vicinity of the grounded anode electrode, namely raw material gas excitation and decomposition reaction are accelerated, resulting in surface treatment rate improvement.

Such self bias control leads to the plasma space potential control and can adjust intentionally the extent of damage due to collision of ion to the substrate. Consequently, for example, when the film formation treatment is to be performed, the crystallinity of its crystalline thin film can be controlled.

In order to generate hollow discharge efficiently at the recess or the through hole, preferably, an opening width W(2) of the smallest portion of the recess or the through hole is set in a range satisfying either of W(2)≦5L(e) or W(2)≦20X. L(e) is an electron mean free path in respect to atom or molecular species (active species) of the smallest diameter among raw material gas species and electrically neutral atom or molecular species (active species) produced therefrom by decomposition, under the desired plasma generation conditions and X is a thickness of a sheath layer generated under the desired plasma generation conditions.

Circular or polygonal cross-section can be adopted for the recess or the through hole, and the shortest dimension portion of this opening shape is taken as the opening width W(2). In addition, it is preferable to set the opening width W(2) of the smallest portion on at least one of the plasma nozzle in a range satisfying also X/20≦W(2), and further in a range satisfying also X/5≦W(2).

Preferably, the hollow plasma generation electrode is a hollow body, the electrode includes one or more through holes communicating with a hollow inside on a portion opposed to the plasma generated by the plasma generation means and, a hollow discharge generation area is made in at least a portion of the hollow inside.

Thus, as the plasma density can further be increased by generating hollow discharge at least in a portion of the hollow inside, the raw material gas excitation and decomposition reaction is remarkably accelerated to increase the surface treatment speed. Besides, when the cathode electrode is used as hollow plasma generation electrode, as the self bias can be brought further to the positive direction potential by increasing the cathode electrode surface area in contact with plasma, raw material gas excitation and decomposition reaction are more accelerated, resulting in a remarkable surface treatment rate improvement.

Concerning an apparatus for surface treatments without negative effect due to collision of ion with the substrate such as etching, ashing, ion doping or the like, the hollow plasma generation electrode can be composed of an anode electrode, the inner wall face of this anode electrode may be used as substrate support table, and the anode electrode inside as the substrate treatment chamber. In this case, the substrate is exposed directly to increase the treatment speed of the hollow anode discharge, and etching, ashing, ion doping or the like. However, such surface treatment apparatus wherein the anode electrode inside is used as substrate treatment chamber is not appropriate for the film formation treatment, as ion impact damage to the substrate is substantial.

Moreover, the hollow plasma generation electrode made of hollow element have preferably one or more partition walls extending in the height direction of the hollow inside, in order to increase its surface area. Namely, it is preferable that the hollow inside of the hollow plasma generation electrode is divided into plural rooms by the partition wall. In this case, it is necessary to form at least one through hole for each of divided areas.

In order to generate effectively hollow discharge in the hollow inside of the hollow plasma generation electrode, preferably, an opposed face distance H in the hollow inside along the formation direction of the through hole of the hollow plasma generation electrode is set in a range satisfying either of H≦5L(e) or H≦20X. L(e) is an electron mean free path in respect to atom or molecular species (active species) of the smallest diameter among raw material gas species and electrically neutral atom or molecular species (active species) produced there from by decomposition, under the desired plasma generation conditions and X is a thickness of a sheath layer generated under the desired plasma generation conditions. In addition, it is preferable to set the opposed face distance H in the hollow inside along the formation direction of the through hole of the hollow plasma generation electrode in a range satisfying also X/20≦H, and further in a range satisfying also X/5≦H.

Besides, preferably, a magnetic field is formed in the vicinity of the plasma nozzle and/or in the vicinity of the recess, through hole and/or in the hollow inside. The “proximity” includes the inside of the plasma nozzle, recess and through hole, or the periphery and proximity of the opening of the plasma nozzle, recess and through hole. Besides, the magnet is preferably disposed so that the magnetic line of flux of its magnetic field becomes parallel to the axial direction of the plasma nozzle, recess and through hole, and, parallel to the electrode face in the hollow inside.

The magnetic field intensity is preferably 1 to 2000 mT at the central section of the plasma nozzle, recess and through hole, or in the hollow inside and more preferably, 5 to 500 mT. Also, the magnetic field intensity is preferably 2 to 2000 mT, and more preferably, 5 to 1000 mT at the inner wall face and in the vicinity of the plasma nozzle and/or recess and through hole, or in the vicinity of the hollow inside.

Such magnetic field disposition allows electrons to remain for a long time in the plasma nozzle where hollow discharge occurs or in the vicinity thereof, inside the recess or through hole where hollow cathode discharge or hollow anode discharge occurs or in the vicinity thereof, or in the hollow inside, by adjusting the electron orbit, and the generation of active species contributing to the surface treatment is accelerated. Consequently, the surface treatment speed increases further. The electron energy does not change by this magnetic field and, therefore, non adversely affecting ion is generated by the electron energy increase, allowing to maintain a high quality surface treatment.

Besides, the apparatus preferably includes potential applying means for applying a desired potential to the substrate. This potential applying means allows to apply a desired potential also to the substrate by applying the potential to the substrate support table on which the substrate is placed. Moreover, the potential applying means includes, as necessary, means for monitoring a potential Vs of process plasma arriving at the substrate or the substrate potential. The process plasma potential Vs is decided by the potential of the electrode in contact with most of the plasma. Consequently, the process plasma potential Vs can be monitored by monitoring, for example, high frequency voltage, self bias of the plasma generation electrode and the like.

For example, if the film formation treatment is performed on a substrate, it is preferable to reduce the differential in voltage between the substrate and the process plasma potential Vs, and more preferably, approximately same potential as the plasma potential Vs is applied, in order to control ion damage from the plasma. The potential applied to the substrate in case of film formation treatment is preferably in the range of ½ to 1 time to the process plasma potential Vs. In addition, when etching it to be performed, the anisotropy can be improved by applying a potential lower than the plasma potential Vs, especially, a minus potential.

Thus, through an intentional control of differential in voltage between the substrate and process plasma by applying a desired potential to the substrate, the film quality control such as plasma damage reduction can be achieved without reducing the treatment speed for the film formation treatment, and anisotropy or other etching form can be controlled for etching treatment.

In addition, it is preferable to protrude a nozzle element on at least one side opening edge of the plasma nozzle and/or recess and through hole. The center line of the nozzle element may be aligned with the axial direction of the plasma nozzle and/or recess and through hole, or the center line of the nozzle element may be disposed making an angle in respect to the axial direction of the plasma nozzle and/or recess and through hole. Besides, the nozzle element shape may be a cylinder having a constant cross section form, or a cylinder reducing or increasing gradually in its cross section dimensions. Moreover, a tubular nozzle element may be disposed in spiral.

By providing the protruding nozzle element at the plasma nozzle and/or recess and through hole, the length dimension of the plasma nozzle and/or recess, through hole can be set as desired without increasing unnecessarily the thickness dimension of members composing the plasma nozzle or the hollow plasma generation electrode, and the plasma density increases and the surface treatment speed is improved, because the hollow discharge generation area of these plasma nozzle and/or recess and through hole increases by increasing this length.

Moreover, the nozzle length of the nozzle element is preferably inconstant. In other words, at the plasma nozzle and/or recess, or plasma nozzle and/or through hole, the length of all nozzle elements thereof is not necessarily uniform, but it may vary conveniently. Thus, by changing the nozzle element length, the intensity of plasma arriving at the substrate can be uniformed all over the surface of this substrate.

### BRIEF DESCRIPTION OF DRAWINGS

FIG. 1 is a schematic view of a surface treatment apparatus according to a first embodiment of the present invention.

FIG. 2 is a schematic view showing a disposition example of a gas inlet according to a modification of the apparatus.

FIG. 3 is a schematic view of a surface treatment apparatus according to a second embodiment of the present invention.

FIGS. 4A and 4B are schematic views showing another disposition example of magnet in respect to a cathode electrode.

FIG. 5 is a schematic view of a surface treatment apparatus according to a third embodiment of the present invention.

FIG. 6 is a schematic view of a surface treatment apparatus according to a fourth embodiment of the present invention.

FIGS. 7A and 7B are schematic views showing another disposition example of a magnet in respect to a hollow cathode electrode.

FIGS. 8A to 8C are schematic views showing still another disposition example of the magnet in respect to the hollow cathode electrode.

FIG. 9 is a schematic view of a cathode electrode according to a modification of the apparatus of the third and fourth embodiments.

FIG. 10 is a schematic view showing a disposition example of a gas inlet in the modification.

FIG. 11 is a schematic view of a surface treatment apparatus according to a fifth embodiment of the present invention.

FIG. 12 is a schematic view of a surface treatment apparatus according to a sixth embodiment of the present invention.

FIGS. 13A to 13C are schematic views showing another embodiment of the hollow cathode electrode.

FIG. 14 is a schematic view of a surface treatment apparatus according to a seventh embodiment of the present invention.

FIG. 15 is a schematic view of a surface treatment apparatus according to an eighth embodiment of the present invention.

FIGS. 16A and 16B are schematic views of a cathode electrode portion which can be applied to a surface treatment apparatus according to the embodiments of the present invention.

FIGS. 17A and 17B are schematic views of another cathode electrode portion which can be applied to a surface treatment apparatus according to the embodiments of the present invention.

FIG. 18 is a schematic view of a surface treatment apparatus according to a ninth embodiment of the present invention.

FIG. 19 is a schematic view of a modification of the anode electrode of the ninth embodiment.

FIGS. 20A and 20B are schematic views of another modification of the anode electrode of the ninth embodiment.

FIG. 21 is a schematic view of a surface treatment apparatus according to a first modification of the ninth embodiment.

FIG. 22 is a schematic view of a surface treatment apparatus according to a second modification of the ninth embodiment.

FIG. 23 is a schematic view of a surface treatment apparatus according to a third modification of the ninth embodiment.

FIG. 24 is a schematic view of a surface treatment apparatus according to a tenth embodiment of the present invention.

FIGS. 25A and 25B are schematic views of a modification of anode electrode according to the tenth embodiment.

FIG. 26A to FIG. 26D are schematic views of a preferred modification of various through holes of the present invention.

FIG. 27 is a horizontal schematic sectional view of a surface treatment apparatus according to an eleventh embodiment of the present invention.

FIG. 28 is a horizontal schematic sectional view of a surface treatment apparatus according to a twelfth embodiment of the present invention.

FIG. 29 is a horizontal schematic sectional view of a surface treatment apparatus according to a thirteenth embodiment of the present invention.

FIG. 30 is a horizontal schematic sectional view of a surface treatment apparatus according to a fourteenth embodiment of the present invention.

FIG. 31 is a horizontal schematic sectional view of a surface treatment apparatus according to a fifteenth embodiment of the present invention.

FIG. 32 is a horizontal schematic sectional view of a surface treatment apparatus according to a sixteenth embodiment of the present invention.

FIGS. 33A to 33C are views each showing a disposition example of a number of through holes or recesses.

FIGS. 34A to 34C are views each showing another disposition example of a number of through holes or recesses.

FIGS. 35A and 35B are views each showing still another disposition example of a number of through holes or recesses.

FIGS. 36A and 36B are views each showing still another disposition example of a number of through holes or recesses.

FIG. 37 is a sectional view schematically showing a surface treatment apparatus according to a seventeenth embodiment of the present invention.

FIG. 38 is a plan view of an anode electrode in the apparatus.

FIGS. 39A and 39B are plan views of an anode electrode according to a modification of the seventeenth embodiment.

FIG. 40 is a plan view of an anode electrode according to another modification of the seventeenth embodiment.

FIG. 41 is a plan view of an anode electrode according to still another modification of the seventeenth embodiment.

FIG. 42 is a plan view of an anode electrode according to still another modification of the seventeenth embodiment.

FIG. 43 is a plan view of an anode electrode according to still another modification of the seventeenth embodiment.

FIGS. 44A and 44B are a plan view and a sectional view of an anode electrode according to still another modification of the seventeenth embodiment, respectively.

### DETAILED DESCRIPTION OF THE PREFERRED EMBODIMENTS

Now, the embodiment of the present invention will be described concretely referring to drawings and preferred embodiments.

FIG. 1 is a schematic view of a surface treatment apparatus 1 according to a first embodiment of the present invention. The apparatus 1 is shielded from the atmosphere, and a grounded casing 2 is divided into two chambers, a plasma generation chamber 3 and a substrate treatment chamber 4.

A pair of plasma generation electrodes 5 and 6 are disposed in parallel vertically in the plasma generation chamber 3. The upper electrode (cathode electrode) 5 connected to a high frequency power supply P of the pair of electrodes 5 and 6, is attached to an upper wall 2a formed by an insulator of the casing 2, while the grounded lower electrode (anode electrode) 6 defines the plasma generation chamber 3 and the substrate treatment chamber 4. Here, the anode electrode 6 is attached to a peripheral wall 2b of the grounded casing 2, it is not limited to this, but it can be attached to any position of the casing 2.

A round communication hole 7 is formed at the center of the anode electrode 6, and the communication hole 7 composes a plasma nozzle 7 of the present invention. The plasma generation chamber 3 and the substrate treatment chamber 4 are connected each other through this plasma nozzle 7. Here, separately from the anode electrode 6, a partition plate to define the plasma generation chamber 3 and substrate treatment chamber 4 can be disposed and a plasma nozzle can be formed on the partition plate.

Though cross section form of the plasma nozzle 7 is circular in this embodiment, it can also be, for example, rectangular, truncated cone shape increasing in its diameter from the plasma generation chamber 3 to the substrate treatment chamber 4, truncated prism shape, and further a shape whose diameter of upstream side approximate half decreases downwards and diameter of downstream side half increases downwards. And moreover, the plasma nozzle 7 may also be a slit form.

An opening width W, that is, a diameter thereof W of the plasma nozzle 7 is set in a range satisfying either of W≦5L(e) or W≦20X. L(e) is an electron mean free path in respect to atom or molecular species (active species) of the smallest diameter among raw material gas species and electrically neutral atom or molecular species (active species) produced therefrom by decomposition, under the desired plasma generation conditions, and X is a thickness of a sheath layer generated under the desired plasma generation conditions. Such range setting can make the plasma nozzle 7 the hollow anode discharge generation area. It is preferable to set the opening width W in a range satisfying X/20≦W, and it is preferable to set the opening width W further in a range satisfying also X/5≦W.

The upper cathode electrode 5 composes a hollow plasma generation electrode of the present invention, a plurality of recesses 5a having circular cross section are disposed on the face of the cathode electrode 5 opposed to the anode electrode 6. The opening width W of this recess 5a, namely the diameter W, is set in a range satisfying either of W≦5L(e) or W≦20X. L(e) is an electron mean free path in respect to atom or molecular species (active species) of the smallest diameter among raw material gas species and electrically neutral atom or molecular species (active species) produced therefrom by decomposition, under the desired plasma generation conditions, and X is a thickness of a sheath layer generated under the desired plasma generation conditions. It is preferable to set the opening width W in a range satisfying X/20≦W, and further it is preferable to set the opening width W further in a range satisfying also X/5≦W. Among the plasma generation conditions, if the gas pressure is in a range 10 to 1400 Pa, the diameter of the recess 5a is set in a range 1 to 100 mm, and more preferably it is 1 to 20 mm. By setting the diameter of the recess 5a in such range, the recess 5a can be made a hollow cathode discharge generation area.

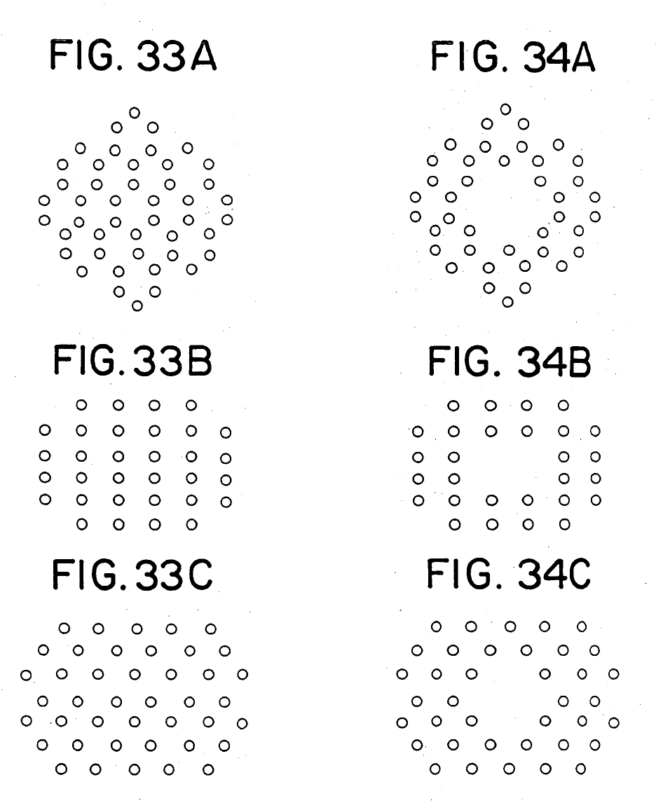

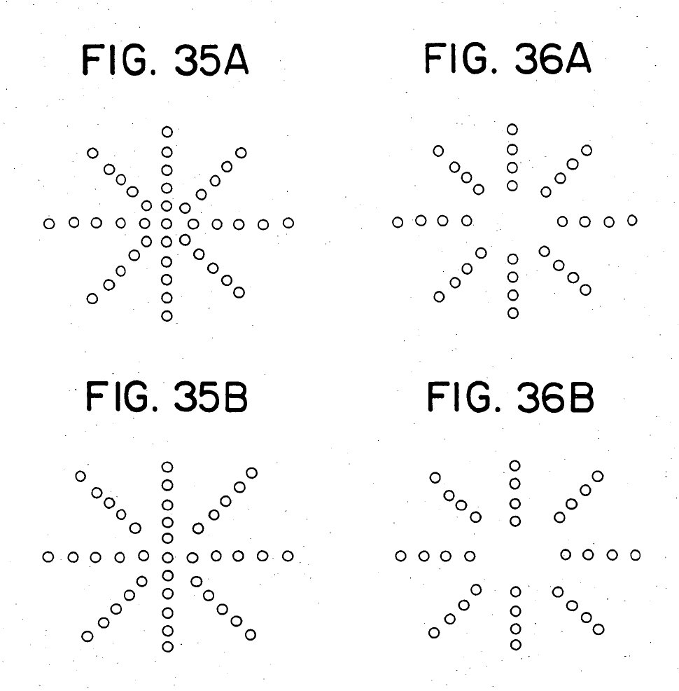

It is preferable to form the plurality of recesses in a disposition as shown in FIG. 33A to FIG. 36B. Disposition based on an equilateral hexagon shown in FIG. 33A, disposition based on a rectangular shown in FIG. 33B, or disposition based on a triangle shown in FIG. 33C are preferable. A disposition wherein the recess 5a is not formed at the center portion of these dispositions, namely right above the plasma nozzle 7, as shown in FIGS. 34A to 34C, is more preferable. Besides, a radial disposition as shown in FIGS. 35A and 35B, or a disposition except for the central portion as shown in FIGS. 36A and 36B are also preferable.

The approximate lower limit of a dimension T in the longitudinal direction (thickness direction) of the plasma nozzle 7 and a depth D of the recess 5a is X/50. The upper limit is decided by the apparatus dimensional restriction, namely, the thickness of the anode electrode 6, or the thickness of the cathode electrode 5. The length T of this plasma nozzle 7 and the depth D of the recess 5a is preferably 0.1 mm to 100 mm for the aforementioned gas pressure and diameter. Here, from the view point of effective generation of hollow discharge, larger dimensions of the length T of the plasma nozzle 7 and the depth D of the recess 5a are advantageous and allow to generate a stronger plasma. Therefore, the substantial length T of the plasma nozzle 7 and the substantial depth D of the recess 5a may be increased by attaching a nozzle element to an opening edge of the plasma nozzle 7 or the recess 5a.

Though the recess 5a has a circular cross section in this embodiment, it may be polygonal. The cross section area is not necessarily constant, and the cross section may vary in the axial direction and, for example, it may be a recess having a bottom face larger or smaller than the opening. Further, the recess 5a may be a groove structure having rectangular form, whorl form or meandering form. In case it is a groove structure having rectangular form, whorl form or meandering form, the opening width W of that recess 5a corresponds to a groove width (dimension between groove walls), and this groove width is set within the aforementioned range. This groove width is not necessarily constant, and may reduce or increase gradually: from the center to the outer periphery of the cathode electrode 5. Also, a partial relief may be formed on the inner wall face of the recess 5a. It is unnecessary to make a plurality of the recesses 5a have identical diameter or shape, and a plurality of recesses 5a having different dimensions and shape may be formed.

In this embodiment, a gas inlet 8 is formed passing through the upper wall 2a of the casing 2 and the cathode electrode 5 and, in case of film formation treatment, mixed gas of raw material gas such as monosilane and carrier gas to accelerate the plasma generation, stabilize the plasma and transport raw material gas to a substrate S, is introduced in the plasma generation chamber 3 from this gas inlet 8. The shape of this gas inlet 8 is not limited to cylindrical form but it may be a rectangular tube.

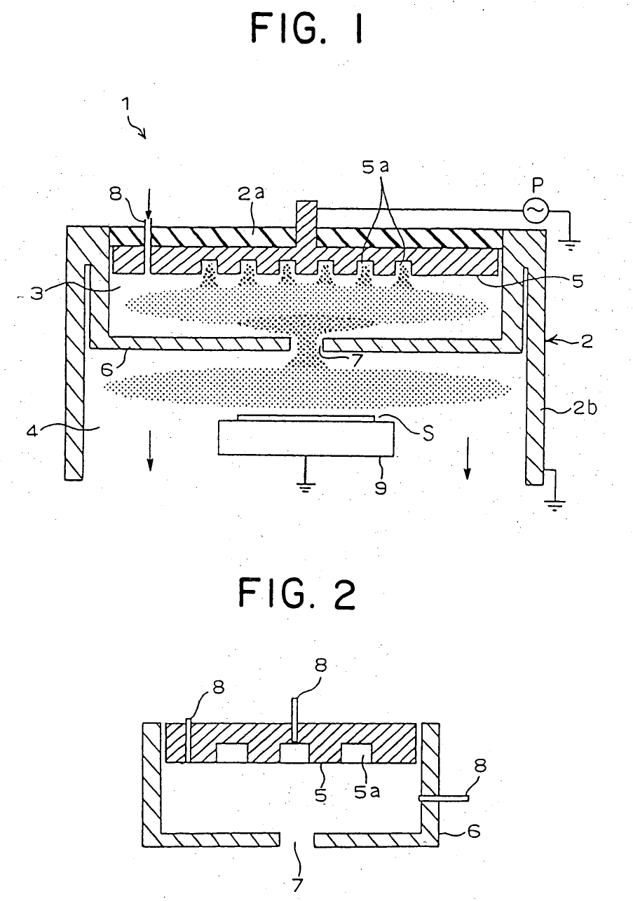

Also, a forming position of the gas inlet 8 is not limited to the aforementioned position. For instance, as shown in FIG. 2, it may formed at the opening position of the bottom section of the recess 5a, or formed at the opening position of the anode electrode 6 on the peripheral wall section. In addition, a plurality of the gas inlets 8 may be formed.

The gas inlet 8 may introduce only carrier gas into the plasma generation chamber 3, and raw material gas may also be introduced inside the plasma generation chamber 3, inside the film formation treatment chamber 4 or in the middle of the plasma nozzle 7 through a different inlet installed separately.

A substrate support table 9 is disposed in the film formation treatment chamber 4 at the position opposed to the plasma nozzle 7. In this embodiment, as the substrate support table 9 is grounded, the substrate S placed on the support table 9 is also grounded. The substrate support table 9, namely the substrate S may be bias applied by a DC or AC-like way, or bias applied pulsatively without grounding. Otherwise, the substrate S can be electrically insulated from the substrate support table 9. Besides, the substrate support table 9 has a built-in heater, for adjusting the temperature of the substrate S placed on an upper face of the substrate support table 9 to a temperature appropriate for vapor growth.

The film formation treatment chamber 4 is adjusted to have a chamber pressure lower than the plasma generation chamber 3 by not shown valve, pressure adjusting valve and vacuum pump.

In case of film formation treatment by the surface treatment apparatus 1, when high frequency power is input from the high frequency source P to the cathode electrode 5, discharge occurs between the electrodes 5 and 6 and plasma is generated in the plasma generation chamber 3. This plasma activates raw material gas and carrier gas introduced into the plasma generation chamber 3, and species contributing to the film formation are generated. At this moment, as the chamber pressure of the substrate treatment chamber 4 is adjusted lower than the plasma generation chamber 3, the plasma in the plasma generation chamber 3 flows out from the plasma nozzle 7 into the film formation treatment chamber 4 by this differential pressure and, further, diffusion. This plasma flow treats the surface of the substrate S in the treatment chamber 4 and form a thin film on the surface of the substrate S.

At this moment, as the plurality of recesses 5a are formed on the cathode electrode 5 and the opening width W of the recess 5a is set in the aforementioned range, the discharge changes from a normal glow discharge to the one including hollow cathode discharge according to the applied high frequency power. Hollow cathode discharge is generated at the recess 5a and new plasma is generated at the recess 5a. Therefore, plasma generated in the plasma generation chamber 3 increases in the density, active species contributing to the film formation increase, to speed up the surface treatment. Besides, the formation of the recess 5a on the cathode electrode 5 increases substantially the surface area of the cathode 5 in contact with plasma. This allow to bring the self bias during the discharge generation further to the plus direction, accelerate raw material gas excitation, decomposition reaction in the vicinity of the grounded anode electrode 6, and speed up the surface treatment.

Further, hollow anode discharge is generated at the plasma nozzle 7 by setting the opening width W of the plasma nozzle 7 within the aforementioned range. As new plasma is generated at the plasma nozzle 7 by this hollow anode discharge, plasma introduced into the substrate treatment chamber 4 increases in its density. Moreover, the electron energy in the plasma generated in the plasma generation chamber 3 is reduced conveniently to an intensity sufficient for generating active species and insufficient for generating ions, when the plasma generated in the plasma generation chamber 3 passes through the plasma nozzle 7 which is hollow anode discharge generation area. Therefore, plasma introduced into the substrate treatment chamber 4 further increases species contributing to the film formation, increases in its density, and in the film formation speed remarkably. Still further, as the ion energy in the plasma also drops when it passes through the plasma nozzle 7 where the hollow anode discharge is being generated, the plasma introduced into the substrate treatment chamber 4 contains little ions which may damage the substrate by collision therewith, to enable a high quality film formation.

In addition, the performance as process plasma is improved, as the plasma decreases its electron temperature and increases the electron density between both electrodes 5 and 6, by the generation of hollow cathode discharge in addition to hollow anode discharge at the plasma nozzle 7. The space potential of plasma generated between both electrodes 5 and 6 also increases, as the high frequency voltage at the cathode electrode 5 reduces and the self bias voltage increases by the hollow cathode discharge. As a result, hollow anode discharge occurs easily at the plasma nozzle 7, and high density plasma is generated at the plasma nozzle 7 by the synergetic effect. For the same reason, electric field concentrates easily in the plasma generation chamber 3, and locally high density plasmatized uneven discharge can be generated.

Though the substrate support table 9, namely the substrate S is grounded as mentioned above in this embodiment, it is also possible to apply a desired potential without grounding the substrate S. For the film formation treatment, it is possible to form a high quality thin film through plasma ion damage reduction, by applying a potential ½ to 1 time of a potential Vs of process plasma arriving at the substrate S to the substrate S and reducing the differential voltage between the substrate and the process plasma.

At this moment, the potential Vs of the process plasma is determined by the potential of electrodes in contact with most of the plasma. Consequently, the process plasma potential Vs can be monitored by monitoring, for example, high frequency voltage and self bias of the cathode electrode or the like.

Though one plasma nozzle 7 having a circular cross section is formed in this embodiment, a plurality of the plasma nozzles 7 may be formed in such disposition as shown in FIG. 33A to FIG. 36B, for example, when the surface treatment is applied to a large area of the substrate S. Further, a substantially continuous slit shape that can be drawn with a single stroke of the brush, such as whorl form or meandering form, allows to treat a large area uniformly.

Where a plurality of holes are provided or shaped in slit, their hole diameter or slit width W is preferably set within the range of the present invention. However, it is not required that a plurality of holes have a constant diameter nor that the slit width is constant in its longitudinal direction. To generate hollow anode discharge evenly, it is desirable to reduce or increase gradually the hole diameter or slit width in their dimension from the central portion of the anode electrode to the outer periphery portion thereof according to various conditions.

Though the anode electrode 6 is grounded in the aforementioned embodiment, the electrodes 5 and 6 may be bias applied respectively by a DC or AC power supply, or by a pulse power supply. Moreover, though, in the embodiment mentioned above, the anode electrode 6 defines the plasma generation chamber 3 and the substrate treatment chamber 4, a partition plate having a plasma nozzle can be disposed separately from the anode electrode 6, to define the plasma generation chamber 3 and the substrate treatment chamber 4.

In this embodiment, inner gas is exhausted from the substrate treatment chamber 4 and, the chamber pressure of the substrate treatment chamber 4 is adjusted to be lower than that of the plasma generation chamber 3. Consequently, inner gas flows from the plasma generation chamber 3 to the substrate treatment chamber 4 in the film formation treatment apparatus, but it is not limited to this. An exhaust outlet for inner gas may be disposed in the plasma generation chamber to inverse the inner gas flow. However, in this case, plasma is transported from the plasma generation chamber 3 to the substrate treatment chamber 4 only by diffusion, and plasma transportation by inner gas flow can not be expected, so the surface treatment speed drops somewhat, but a faster treatment than the prior art is assured.

When the aforementioned apparatus is used for other surface treatments such as ashing, etching or ion doping, the surface treatment can be performed at a lower temperature and faster than before. In case of etching treatment for example, the anisotropy can be improved by applying a potential lower than the process plasma potential Vs, especially a negative potential, to the substrate S.

Now the other embodiments of the present invention will be described concretely referring to drawings. In the following description, the reference numerals will be used for the same composition as the aforementioned first embodiment, and detailed description thereof will be omitted.

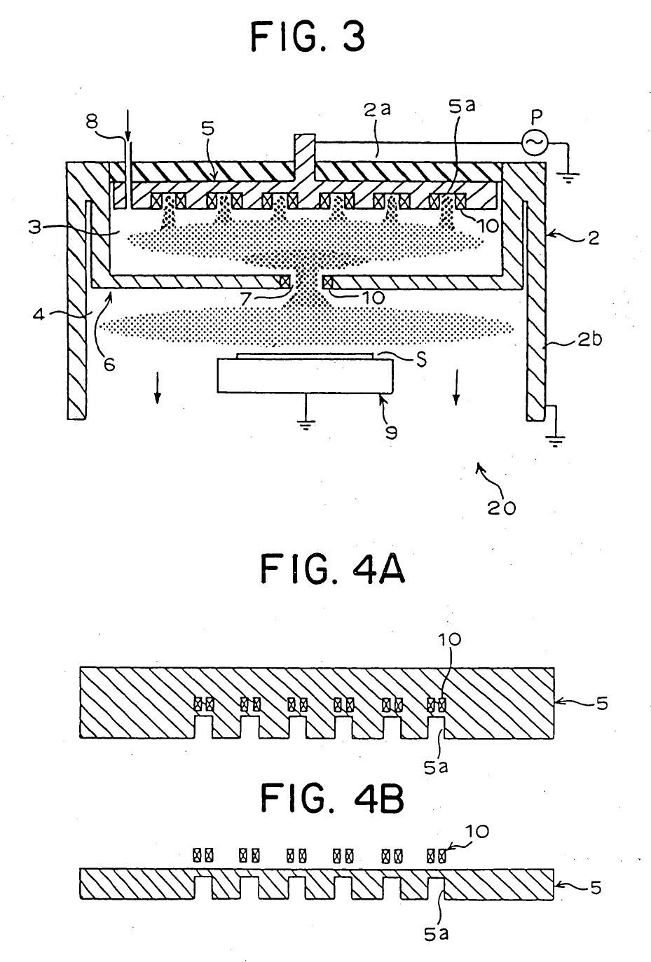

FIG. 3 is a schematic view of a surface treatment apparatus 20 according to a second embodiment. The apparatus 20 is different from the aforementioned first embodiment in that a magnet 10 is disposed on the inner wall face of the recess 5a formed on the cathode electrode 5 and on the inner wall face of the plasma nozzle 7, but otherwise, the composition is similar to the surface treatment apparatus 1 of the aforementioned first embodiment. It will be enough that the magnet 10 is disposed to impart magnetic field to the recess 5a or the plasma nozzle 7. Therefore, the magnet 10 may be embedded in the inner wall face as shown in FIG. 3, and also it may be embedded over the recess 5a in the cathode electrode 5 as shown in FIG. 4A, disposed outside the cathode electrode 5 as shown in FIG. 4B, or further the combination of these dispositions. As for the disposition of these magnets 10, it is preferable to attach the magnet 10 so as not to expose the magnet 10 directly to the plasma.

The magnetic field of the magnet 10 is preferably applied so that flux of the magnetic line becomes parallel to the respective axial direction of the recess 5a and the plasma nozzle 7. The intensity of the magnet is 1 to 2000 mT at the respective axial center of the recess 5a and the plasma nozzle 7, 2 to 2000 mT at the inner wall face and the vicinity thereof, and more preferably, 5 to 500 mT at the axial center, and 5 to 1000 mT at the inner wall face and the vicinity thereof.

Such magnetic field formation at the recess 5a and plasma nozzle 7 allows electrons to remain for a long time in the recess and plasma nozzle 7 by adjusting the electron orbit in the plasma generated there. Such the electron orbit adjustment makes the electron acting time to the raw material gas longer without elevating the electron energy (electron temperature), and the generation of active species is accelerated, improving the film formation speed.

Besides, the magnetic field formation by disposing magnets 10 extends the dimensional tolerance of opening width W or depth D of the recess 5a and opening width W of the plasma nozzle 7 approximately by 30% more than the case without magnet disposition.

Though the magnets 10 are disposed on all recesses 5a and plasma nozzles 7 in this embodiment, the magnets 10 may also be disposed only on the selected ones, in place of providing all of them with the magnet 10. Further, magnetic field may also be formed by electromagnet or other means. Magnetic field disposition including the magnet polarity and the intensity thereof are set arbitrarily so as to increase the plasma density.

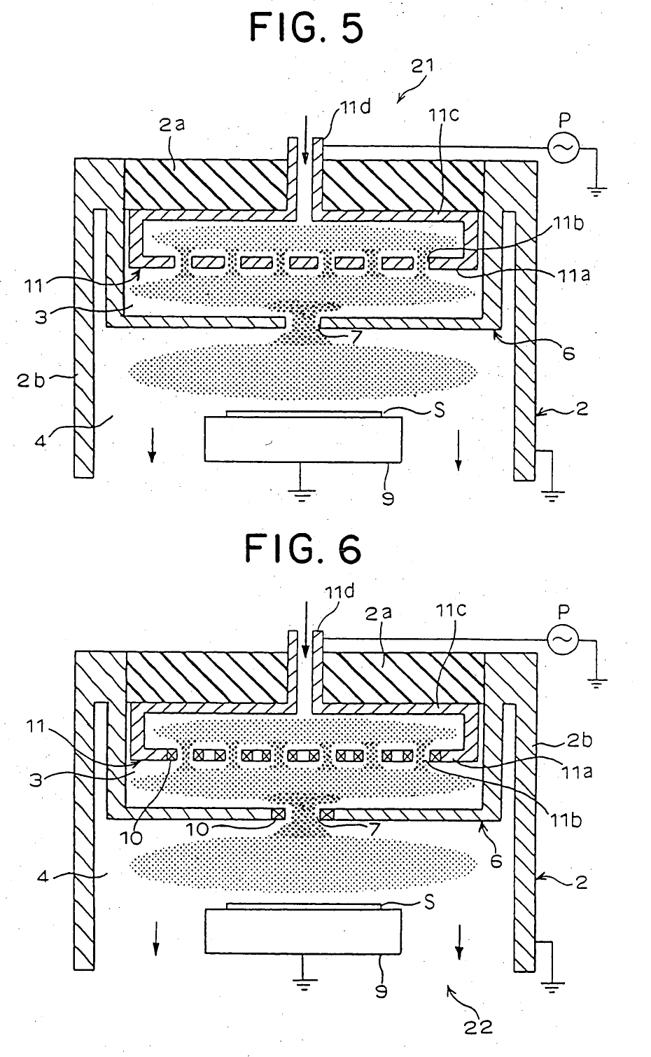

FIG. 5 is a schematic view of a surface treatment apparatus 21 according to a third embodiment. The apparatus 21 is different from the aforementioned first embodiment in that the cathode electrode 11 which is the hollow plasma generation electrode of the present invention is a hollow element of hollow cylindrical form, but otherwise, the composition is similar to the surface treatment apparatus 1 of the aforementioned first embodiment.

In the cathode electrode 11 which is the hollow element, a plurality of through holes 11b having a circular cross section communicating with the hollow inside, at the portion opposed to the anode electrode 6, namely at a lower wall section 11a of the cathode electrode 11. These through holes 11b are preferably formed in the disposition as shown in FIG. 33A to 36B. More preferably, these through holes 11b are formed at the position avoiding just above the plasma nozzle 7 formed in the anode electrode 6, namely at the disposition as shown in FIGS. 34A to 34C or FIGS. 36A and 36B.

In order to make this through hole 11b the hollow cathode discharge generation area, the opening width W thereof, namely the diameter W is set in a range satisfying either of W≦5L(e) or W≦20X. L(e) is an electron mean free path in respect to atom or molecular species (active species) of the smallest diameter among raw material gas species and electrically neutral atom or molecular species (active species) produced therefrom by decomposition, under the desired plasma generation conditions, and X is a thickness of a sheath layer generated under the desired plasma generation conditions. It is preferable to set the opening width W in a range satisfying X/20≦W, and it is preferable to set the opening width W further in a range satisfying also X/5≦W.

The opening width W of all of the plurality of through holes 11b is not necessarily identical, it can be set to different opening width W conveniently, in order to produce hollow cathode discharge evenly across the plurality of through holes 11b. Especially, it is preferable to reduce the opening width W of the through hole 11b in the vicinity of the center and increase the opening width W progressively towards the outer periphery, or increase the opening width W in the vicinity of the center and reduce the opening width W thereof progressively towards the outer periphery, according to the applied electricity frequency or other conditions.

Among the plasma generation conditions, if the gas pressure is in a range 10 to 1400 Pa, the diameter of the through hole 11b is set in a range of 1 to 100 mm, and more preferably it is 1 to 20 mm. By setting the diameter of the trough hole 11b in such range, hollow cathode discharge occurs in the trough hole 11b.

The approximate lower limit of the length T of the trough hole 11b, namely the thickness T of the lower wall section 11a for this embodiment is X/50. The upper limit is decided by the apparatus dimensional restriction. The length T of this trough hole 11b is preferably 0.3 to 70 mm for the aforementioned gas pressure and diameter.

Though the through hole 11b has a circular cross section in this embodiment, it may have an oval, rectangular, polygonal, undefined form or other arbitrary form. The cross section is not necessarily constant, and the cross section may change in the axial direction. Moreover, the trough hole 11b may be a slit structure having a rectangular cross section, or a slit structure having a two-dimensional extension such as whorl form or meandering form. When such slit structure is adopted, the opening width W of this through hole 11b corresponds to the slit width and this slit width is set within the aforementioned range. This slit width is not necessarily constant, and increase or reduce gradually from the center to the outer periphery. Also, a partial relief may be formed on the inner wall face of the through hole 11b. It is unnecessary to make a plurality of the through holes 11b identical each other in dimensions or shape, and a plurality of through holes 11b having different dimensions and shape may be formed.

In this embodiment, in order to make the hollow inside of the cathode electrode 11 the hollow cathode discharge generation area, the opposed face distance in the hollow inside along the formation direction of the through hole 11b of the cathode electrode 11, namely a height H vertical in the drawings is set in a range satisfying either of H≦5L(e) or H≦20X. L(e) is an electron mean free path in respect to atom or molecular species (active species) of the smallest diameter among raw material gas species and electrically neutral atom or molecular species (active species) produced therefrom by decomposition, under the desired plasma generation conditions, and X is a thickness of a sheath layer generated under the desired plasma generation conditions. It is preferable to set the height of hollow inside H in a range satisfying X/20≦H, and further it is preferable to set the height H in a range satisfying also X/5≦H. Among the plasma generation conditions, if the gas pressure is in a range 10 to 1400 Pa, and the dimensions of the through hole 11b is in the range mentioned above, the height H inside the hollow is set preferably to be 1 to 100 mm, and more preferably the height H inside the hollow is set to be 1 to 20 mm.

Though, the height H of the hollow inside is constant in the drawing, the height H is not necessarily constant. It is preferable to reduce the height H of the hollow inside in the vicinity of the center, increasing gradually its height H in the outer peripheral direction, or increase the height H of the hollow element in the vicinity of the center, reducing gradually its height H in the outer peripheral direction, according to the applied power frequency or other condition, in order to uniform hollow cathode discharge substantially in the whole area of the hollow inside.

Though the cathode electrode 11 is a hollow element having an approximately uniform thickness in the wall section and being hollow as the whole in the illustrated embodiment, the peripheral wall section may be made thick and only the central portion may be made hollow, or a locally hollow portion may be formed. Moreover, a recess may be formed in that hollow portion.

A cylindrical gas inlet 11d is formed at the center of the upper wall section 11c of the cathode electrode 11 and, mixed gas of raw material gas such as monosilane and carrier gas to accelerate the plasma generation, stabilize the plasma and transport raw material gas to the substrate S, is introduced into the hollow inside of the cathode electrode 11 from this gas inlet 11d. The shape of this gas inlet 11d is not limited to cylindrical form but it may be a rectangular tube. In addition, the formation position of the gas inlet 11d is not limited to the center of the upper wall section 11c, but it may be formed at any position.

The mixed gas introduced inside the cathode electrode 11 from such gas inlet 11d is introduced in shower form into the plasma generation chamber 3 from the through holes 11b. Thus, the mixed gas can be introduced in the plasma generation chamber 3 with an uniform density and pressure, by retaining once the mixed gas inside the cathode electrode 11 and then introducing into the plasma generation chamber 3 in shower form through the through holes 11b.

Only carrier gas may introduced into the cathode electrode 11 hollow inside, and raw material gas may be introduced inside the plasma generation chamber 3, inside the film formation treatment chamber 4 or in the middle of the plasma nozzle 7 through a different inlet installed separately.

When a high frequency power is input from the high frequency power source P to the cathode electrode 11, discharge occurs between the electrodes 11 and 6 and plasma is generated in the plasma generation chamber 3. The discharge changes from a normal glow discharge to the one including hollow cathode discharge according to the applied high frequency power. As for the cathode electrode 11, hollow cathode discharge is generated at the through hole 11b and new plasma is generated at the through hole 11b and hollow cathode discharge is also generated in the hollow inside of the cathode electrode 11 and new plasma is generated. Therefore, plasma generated in the plasma generation chamber 3 increases in the density, and the active species contributing to the film formation increase so as to speed up the surface treatment.

Further, as the cathode electrode 11 is a hollow element and the through holes 11b are provided so that plasma is generated in the through holes 11b and the hollow inside, the surface area of the cathode electrode 11 substantially in contact with plasma increases further than the case of the first embodiment mentioned above. This allow to bring the self bias during the discharge generation further to the plus direction further, accelerate raw material gas excitation, decomposition reaction in the vicinity of the grounded anode electrode 6, and speed up the surface treatment.

<Experiment 1>

In a surface treatment apparatus 21 according to the third embodiment, the diameter of the through hole 11b of the cathode electrode 11 was set to 2 to 20 mm, the length dimension T of the through hole 11b 2 to 8 mm, the height H of the hollow inside 2 to 20 mm, the hydrogen gas pressure 133 Pa and an RF power of 3.56 MHz in frequency was applied by 0.02 W/cm². As a result, hollow anode discharge was generated at the plasma nozzle 7 and hollow cathode discharge was generated in the through holes 11b of the cathode electrode 11 and in the hollow inside thereof.

At this time, even the lowest value of the cathode electrode 11 self bias was −9 V. On the contrary, for the ordinary regular discharge type where the diameter of the through hole 11b of the cathode electrode 11 is 1 mm, and hollow cathode discharge is not generated in the through hole 11b and in the hollow inside, the cathode electrode self bias is −30 V for the same gas pressure and RF power, and the self bias is −74V for the ordinary parallel flat plate type. This teaches that, in the surface treatment apparatus 21 of the aforementioned embodiment the self bias of the cathode electrode 11 shifted extremely toward the plus side. It is also possible to change the polarity to shift the self bias toward the positive potential depending on conditions.

Besides, in the aforementioned conditions, when the length dimension T of the through hole 11b of the cathode electrode 11 was set to 9 mm, hollow cathode discharge was not generated in the through hole 11b and, hollow cathode discharge was not generated in the hollow inside of the cathode electrode 11, neither. When the RF power was increased, keeping the length dimension T of the through hole 11b at 9 mm, hollow cathode discharge was generated in the through hole 11b of the cathode electrode 11 and in the hollow inside thereof, at 0.05 W/cm².

Next, when the diameter of the through hole 11b of the cathode electrode 11 was set to 5 mm, and the height H of the hollow inside of the cathode electrode 11 to 2 mm, hollow cathode discharge was not generated in the hollow inside when the RF power is equal or inferior to 0.02 W/cm , but self bias of the cathode electrode 11 was −6 V, shifted extremely toward the plus side. When the height H is set to 9 mm, hollow cathode discharge was not generated in the hollow inside when the RF power is equal or inferior to 0.05 W/cm², but in this case also, self bias of the cathode electrode 11 was −9 V, a higher voltage compared to the aforementioned regular discharge type or normal parallel flat type.

<Experiment 2>

Using the surface treatment apparatus 21 and monosilane gas (SiH₄) as raw material gas by the flow rate of 7 cm³/min and introducing hydrogen gas as carrier gas by the flow rate of 105 cm³/min, setting the pressure of the film formation chamber at 29 Pa, the substrate temperature 150 to 260° C. and applying a high frequency power of 13.56 MHz, 0.1 W/cm², the film formation treatment was performed onto a white glass plate substrate. As a result, a fine crystalline thin film was formed on the substrate surface even when the substrate temperature was as low as 150° C. In this temperature range, the fine crystalline thin film formation maximum speed was 40 Å/sec, allowing to realize a high speed film formation that was not achieved by the prior art. Moreover, an extremely fast film formation as 150 Å/sec can be realized by optimizing the film forming conditions and by setting the substrate temperature to 300° C., and in such a fast film formation, the thin film was fine crystallized, providing a thin film that can function sufficiently as a solar cell. It goes without saying that film can be formed still faster, if an amorphous thin film is to be formed.

<Experiment 3>

Using the surface treatment apparatus 21, setting the frequency of the high frequency power source P to 105 MHz, the pressure of the substrate treatment chamber 3 to 10 to 1400 Pa and the substrate temperature to 100 to 450° C., non amorphous crystalline silicone thin film could be created within the range of 0.5<R, where R is hydrogen gas flow rate/monosilane gas flow rate which means a ratio of carrier gas hydrogen flow rate to raw material gas monosilane gas (SiH₄) flow rate. A p-i-n structure solar cell was manufactured, for confirming that it works as a solar cell.

Conventionally, it has been believed that crystallization is difficult especially if R is in the range of 0.5<R<20; however, it was confirmed by X ray diffraction or Raman spectroscopy that a crystalline thin film equal or better than the case where R is high, namely, where the hydrogen flow rate is larger than monosilane gas flow rate can be obtained.

Specific treatment conditions and film formation speed with which a crystalline thin film can be formed under these conditions are shown as examples in the following Table 1.

TABLE 1

| | Film formation | | | Monosilane | | |
|---|---|---|---|---|---|---|
| | chamber | Substrate | Hydrogen | gas flow | | Film formation |
| | pressure | temperature | flow rate | rate | RF power | speed |
| | (Pa) | (° C.) | (sccm) | (sccm) | (W/cm²) | (μm/min) |
| Sample 1 | 80 | 100-450 | 30 | 9 | 1 | 0.26 |
| Sample 2 | 133 | 100-450 | 30 | 9 | 1.5 | 0.56 |
| Sample 3 | 55 | 100-450 | 10 | 9 | 1.25 | 0.28 |
| Sample 4 | 80 | 100-450 | 80 | 4.5 | 0.6 | 0.24 |

*Film formation speed is a speed at which a crystalline thin film can be formed

All crystalline thin films of the aforementioned Samples 1 to 4 were confirmed to be crystalline thin film oriented to (220) by X ray diffraction.

In addition, when these thin films are to be applied to p-i-n type solar cell, the solar cell efficiency is improved by laminating n type and i type (said conditions) and then laminating a thinner i type layer with lower power and lower speed than said condition, before laminating p type layer for making a cell. For example, the solar cell efficiency was improved by 50% by inserting i layer of 5 to 100 nm in thickness under the conditions of 80 Pa, 100 to 450° C., H₂; 40 sccm, SiH₄; 1.5 sccm, RF power; 0.25 W/cm², and setting the film formation speed at 0.01 μm/min.

Such improvement of film formation speed can be explained by, first, the realization of high density plasma by hollow anode discharge at the plasma nozzle 7 and hollow cathode discharge at the through hole 11b of the cathode electrode 11 and the hollow inside thereof. Further, the increase of the surface area of the cathode electrode 11 in contact with plasma allows to bring its self-bias to the plus side and plasma is generated also in the vicinity of the anode electrode, permitting to lead plasma to the substrate surface effectively through the plasma nozzle 7 to the substrate treatment chamber 4. Besides, as the control of the self bias allows to control the plasma space potential at the same time, the crystallization at high speed film formation is believed to be realized by setting this plasma space potential conveniently and imparting a convenient ion impact according to the film formation speed.

The substrate treatment apparatus 21 mentioned above could perform the surface treatment at a lower temperature and faster than before, when it is applied to the surface treatment other than film formation, such as ashing, etching, ion doping or the like.

FIG. 6 is a schematic view of a substrate treatment apparatus 22 according to a fourth embodiment of the present invention. The composition of the apparatus 22 is identical to the substrate treatment apparatus 21 of the aforementioned third embodiment except that magnets 10 are arranged on the inner wall face of the through holes 11b formed across the cathode electrode 11, which is a hollow element, and on the plasma nozzle 7 inner wall face.

The magnetic field of the magnet 10 is preferably applied such that the magnetic line of flux is directed parallel to the respective axial directions of the through hole 11b and the plasma nozzle 7. The magnet intensity is preferably 1 to 2000 mT at the respective axial center of the through hole 11b and plasma nozzle 7, 2 to 2000 mT at the inner wall face and in the vicinity thereof, and more preferably 5 to 500 mT at the axial center, and 5 to 1000 mT at the inner wall face and in the vicinity thereof.

Such magnetic field formation at the through hole 11b and plasma nozzle 7 allows electrons to remain for a long time in the through hole 11b and plasma nozzle 7 by adjusting the orbit of electrons in the plasma generated therein. Such electron obit adjustment accelerates the generation of active species and improves the film formation speed, as the electron acting time to the raw material gas is extended without increasing the electron energy (electron temperature).

Besides, the magnetic field formation by disposing magnets 10 extends the dimensional tolerance of the opening width W and the length T of the through hole 11b and the opening width W of the plasma nozzle 7 approximately by 30% more than the case without magnet disposition.

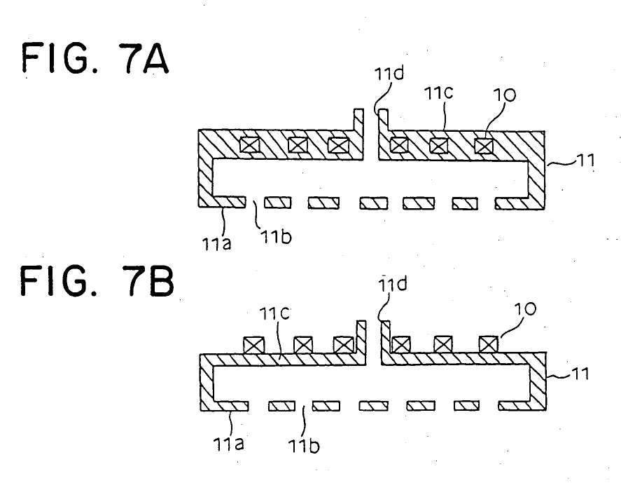

Though all of through holes 11b and plasma nozzles 7 are provided with the magnet 10 in this embodiment, the magnet 10 may be disposed only on the selected ones, in place of providing all of them with the magnet 10. The magnetic field may well be formed by electromagnet or other means. Moreover, the magnet 10 may be embedded in the inner wall face of the through holes 11b and plasma nozzles 7. In addition, it may also be embedded in the upper wall section 11c of the cathode electrode 11, which is a hollow element, as shown in FIG. 7A, or disposed outside the cathode electrode 11 and above the upper wall section 11c as shown in FIG. 7B. Magnetic field disposition including the polarity of the magnet 10 and the intensity thereof are set arbitrarily in a way to increase the plasma density.

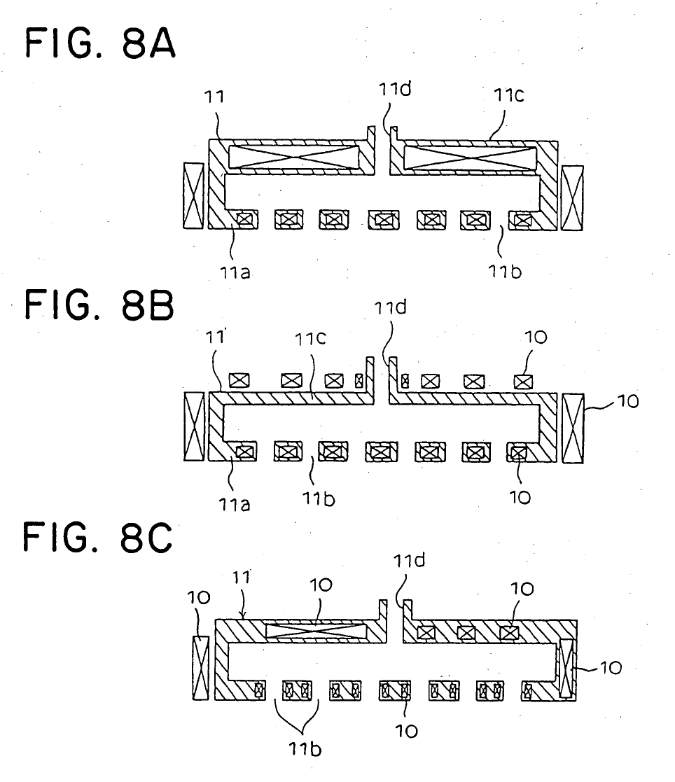

It is also possible to arrange the magnet so as to form a magnetic filed in the hollow inside also, so that hollow cathode discharge in the hollow inside becomes more dense. In this case, it is preferable to impart the magnetic field so that magnetic lines of flux in the hollow inside become parallel with the electrode surface. For example, as shown in FIG. 8A, they may be arranged in the upper and lower wall sections 11c and 11a of the cathode electrode 11 and outside the peripheral wall section of the cathode electrode 11 or as shown in FIG. 8B, they may be arranged outside the cathode electrode 11, above the upper wall section 11c, inside the lower wall section 11c of the cathode electrode 11 and outside the peripheral wall section. They may well be embedded inside the peripheral wall section as shown in FIG. 8C. Note that FIG. 8C describes various kinds of arrangements collectively.

These drawings show only examples of arrangement, and the position or number of magnet 10 arrangement are not limited to those disclosed in the drawings. Magnet arrangement and magnetic field intensity can be set arbitrarily to increase the density of hollow cathode discharge in the hollow inside or through hole 11b, by embedding the magnet 10 inside the cathode electrode 11 or arranging outside, or by the combination thereof. It is preferable that these magnets 10 are attached not to be exposed directly to plasma.

<Experiment 4>

Using the surface treatment apparatus 22 according to the fourth embodiment shown in this FIG. 6, under the conditions as the Experiment 2 of the aforementioned third embodiment, namely, introducing monosilane gas (SiH₄) at the flow rate of 7 cm³/min and hydrogen gas at the flow rate of 105 cm³/min, setting the pressure of the film formation chamber at 29 Pa, the substrate temperature 150 to 260° C. and applying a high frequency power of 13.56 MHz, 0.1 W/cm², the film formation treatment was performed onto a white glass plate substrate. As a result, a thin film was formed at 70 Å/sec, allowing to realize a high speed film formation 75% higher than the aforementioned third embodiment, and in such a fast film formation, the thin film was fine crystallized, providing a thin film that can function sufficiently as a solar cell.

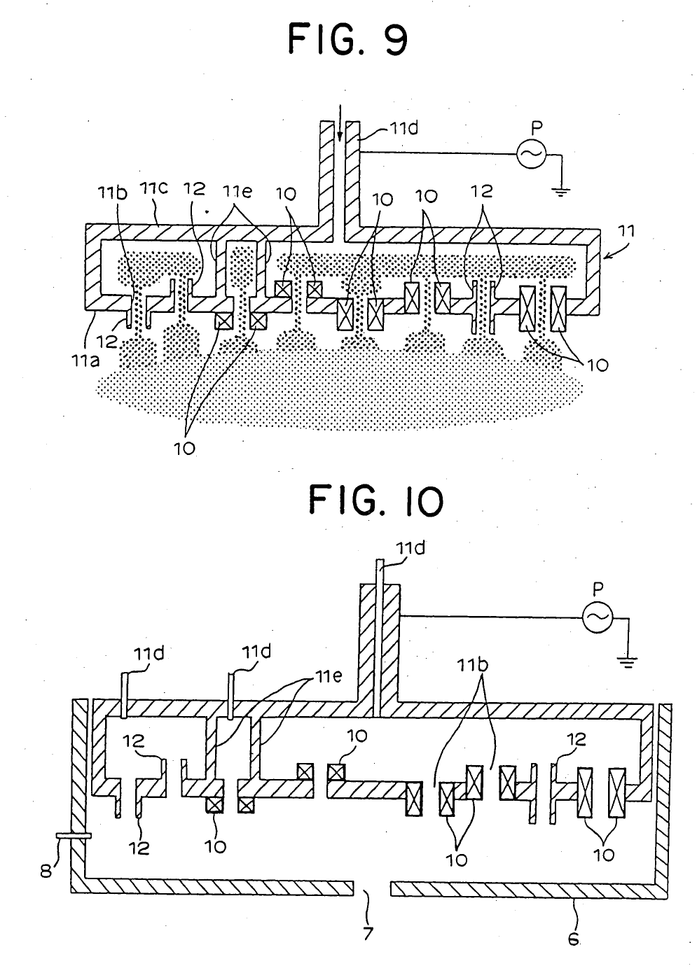

Now, a modification for increasing the density of plasma generated by hollow cathode discharge in the through hole 11b of the cathode electrode 11 or its hollow inside is shown in FIG. 9.

First, from the view point of effective generation of hollow cathode discharge in the through hole 11b, it is preferable to enlarge the length T of the through hole 11b, to generate stronger plasma. However, the thickness of the lower wall section 11a of the cathode electrode 11 is preferably minimum for resisting the gas pressure introduced into the hollow inside and the applied electricity, from the viewpoint of material cost.

Therefore, to increase the length T of the through hole 11b, it is preferable to attach a nozzle element 12 at the periphery of the through hole 11b. This nozzle element 12 may protrude from the through hole 11b to the plasma generation chamber 3 side, or protrude into the hollow inside. It may also protrude to both sides. The same nozzle element 12 may also be composed of magnet 10 as shown in FIG. 9. However, it is preferable that the magnet 10 is not exposed directly to plasma.

Though all nozzle elements 12 shown in FIG. 9 are disposed aligning its center line with the line of the through hole 11b, the centrer line of the nozzle element 12 and the axial line of the through hole 11b may make a certain angle, namely, the nozzle element 12 may be disposed on the slant. Though the nozzle element 12 shown in FIG. 9 is a cylinder having a constant cross section, the shape is not limited to this, but it may be a cylinder having a shape gradually increasing or reducing its cross section. Moreover, tubular nozzle elements can be disposed in spiral. Such variation of the nozzle element can also be applied to the nozzle element attached to the aforementioned plasma nozzle or recess.

Moreover, in order to increase the surface area of the cathode electrode 11 in contact with plasma, the hollow inside of the cathode electrode 11 may by partitioned by a partition wall 11e extending in its height direction. As the surface area can be adjusted freely, the self-bias of the cathode electrode 11 can be controlled freely. The partition wall 11e is not necessarily in contact with the upper and lower partition sections 11c and 11a of the cathode electrode 11, and respective spaces partitioned with gap may communicated each other.

It is preferable that respective partitioned space is provided respectively with a gas inlet 11d as shown in FIG. 10. Alternatively, a gas inlet 8 can be formed at an opening position at the peripheral wall section of the anode electrode 6 and a plurality of these gas inlets 8 and 11d may be formed in plural by the combination thereof. The gas inlet 11d of the cathode electrode 11 may introduce only carrier gas, and raw material gas may also be introduced via the gas inlet 8 of the anode electrode 6, or through a different inlet installed separately to inside the plasma generation chamber 3, inside the film formation treatment chamber 4 or in the middle of the plasma nozzle 7.

Though FIG. 9 illustrates shapes of the plurality of through holes 11b, it is not limited to the illustrated embodiment where all through holes 11b have different shapes. All through holes 11b may have the same shape, or several kinds of through holes 11b may coexist. Also, the length dimension of the nozzle element 12 may be identical for all through holes 11b or may vary conveniently, to uniform the intensity of plasma attaining the substrate surface all over the substrate surface area. Besides, the position and the number of partition wall formation are not limited to the FIG. 9, but they can be designed freely according to the plasma intensity required for the surface treatment.

Also, it is known that, as a factor affecting the plasma intensity, the elevation of high frequency excitation power supply frequency accelerates the crystallization. So, an experiment is made to vary the frequency.

<Experiment 5>

In the experiments 1, 2 and 4 mentioned above, a high frequency power excitation power supply frequency was set to 13.56 MHz; it was changed to 105 MHz, and the film formation treatment was performed under the same conditions, and as a result, the thin film was crystallized even at the film formation speed of 260 Å/sec by an effect of the high frequency in addition to the effects in the respective experiments. When the film formation speed was 240 Å/sec, the crystallized film that can function sufficiently as a solar cell was obtained.

Hollow cathode discharge is generated in almost all area of the hollow inside of the cathode electrode 11, as shown in FIGS. 5, 6 and 9, for the aforementioned third and fourth embodiments and their modifications where the cathode electrode 11 is a hollow element. However, hollow cathode discharge is not necessarily generated in all the area of the hollow inside, according to the height of the hollow inside of the cathode electrode 11, shape, quantity or disposition of the through hole 11d, or the magnet 10 disposition, and hollow cathode discharge is generated only in part of the hollow inside, or hollow cathode discharge may sometimes be generated unevenly in the hollow inside. Generally, hollow discharge brighter than elsewhere is generated in the hollow inside, in the hollow section in the vicinity of the through hole generating the hollow discharge.

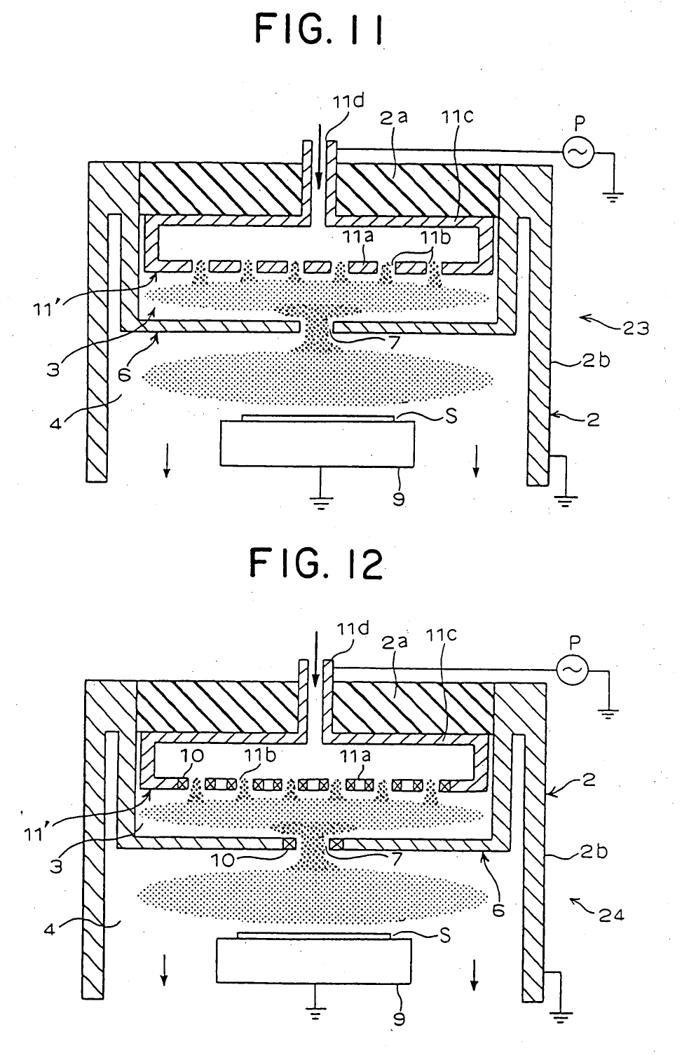

FIG. 11 is a schematic view of a surface treatment apparatus 23 according to a fifth embodiment of the present invention. The apparatus 23 is different from the aforementioned third embodiment in that the inner wall face of the hollow inside is composed of an insulator so that hollow cathode discharge is not generated in the hollow inside of the cathode electrode 11′, but otherwise, the composition is similar to the surface treatment apparatus 21 of the aforementioned third embodiment.

However, the electrode may partially be exposed on the inner face of the lower wall section 11a of the cathode electrode 11′, and in this case, plasma generated in the plasma generation chamber 3 penetrates into the hollow inside through the through holes 11b to creep over this exposed electrode face. Thereby, the surface area of the cathode electrode 11′ substantially in contact with plasma increases, allowing to increase the self bias.

In order to prevent hollow cathode discharge from being generated in the hollow inside of the cathode electrode 11′, in addition to the aforementioned composition of the inner wall surface with an insulator, the height H of the hollow inside may be increased, however, it is more reliable to compose the inner wall surface with an insulator, because this height H may vary depending on RF power or gas pressure.

Thus, plasma can be generated with the intensity corresponding to the application, because not only the plasma generation site can be controlled, but also the surface area of the cathode electrode 11′ in contact with plasma can be adjusted, and the self bias can be controlled.

<Experiment 6>

The film formation treatment was performed using the aforementioned surface treatment apparatus 23, under the conditions as the aforementioned Experiment 2, and hollow cathode discharge was generated in the through holes 11b, hollow anode discharge is generated in the plasma nozzle 7, and plasma density increased, allowing to form fine crystalline thin film was at a high speed. Besides, the obtained crystallized film could function sufficiently as a solar cell.

FIG. 12 is a schematic view of a surface treatment apparatus 24 according to a sixth embodiment of the present invention. The surface treatment apparatus 24 corresponds to the surface treatment apparatus 23 of the aforementioned fifth embodiment wherein magnets 10 are arranged on the inner wall face of the through hole 11b of the cathode electrode 11b and on the inner wall face of the plasma nozzle 7.

<Experiment 7>

The film formation was performed using the aforementioned surface treatment apparatus 24 of the sixth embodiment, under the conditions same as the aforementioned Experiment 2, resulting in the improvement of film formation speed or battery efficiency by 10% or more compared to the aforementioned Experiment 6.

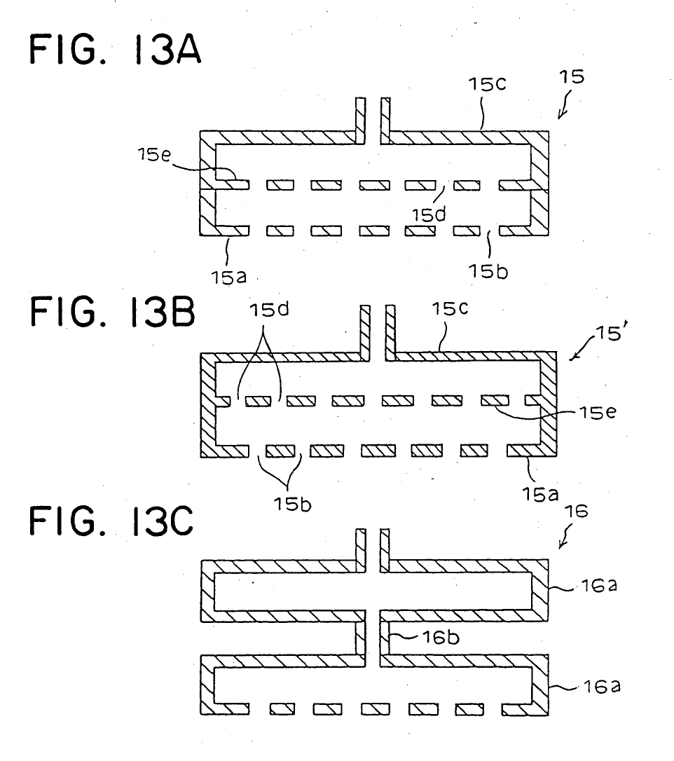

As a modification of the aforementioned cathode electrode 11, which is the hollow element, for example, the space between the lower wall section 15a including a plurality of through holes 15b communicating with the hollow inside and the upper wall section 15c may be partitioned into a plurality of stages by one or more partition walls 15e including one or more through holes 15d, like as the cathode electrode 15 which is a hollow element shown in FIG. 13A. At this time, it is preferable to form respective through holes 15b and 15d such that a plurality of through holes 15b formed at the lower wall section 15a, and a plurality of through holes 15d formed at the partition wall 15e do not overlap, like as the cathode electrode 15′ which is a hollow element shown in FIG. 13B.

Also, the number of the through holes 15b of the lower wall section 15a may be different from the through holes 15d of the partition wall 15e. The opening dimension of respective through holes 15b and 15d may also be different for. Further, for the plurality of through holes 15b formed at the lower wall section 15a, and the plurality of through holes 15d formed at the partition wall 15e, the opening dimension is not necessarily uniform, but the opening dimension may vary to reduce or increase gradually from the central portion to the outer periphery direction.

As a further modification of the aforementioned cathode electrode 11 which is a hollow element, a plurality of hollow electrode members 16a may be connected in a plurality of vertical stages by means of a communication hole 16b, as cathode electrode 16 made of hollow element shown in FIG. 13C.

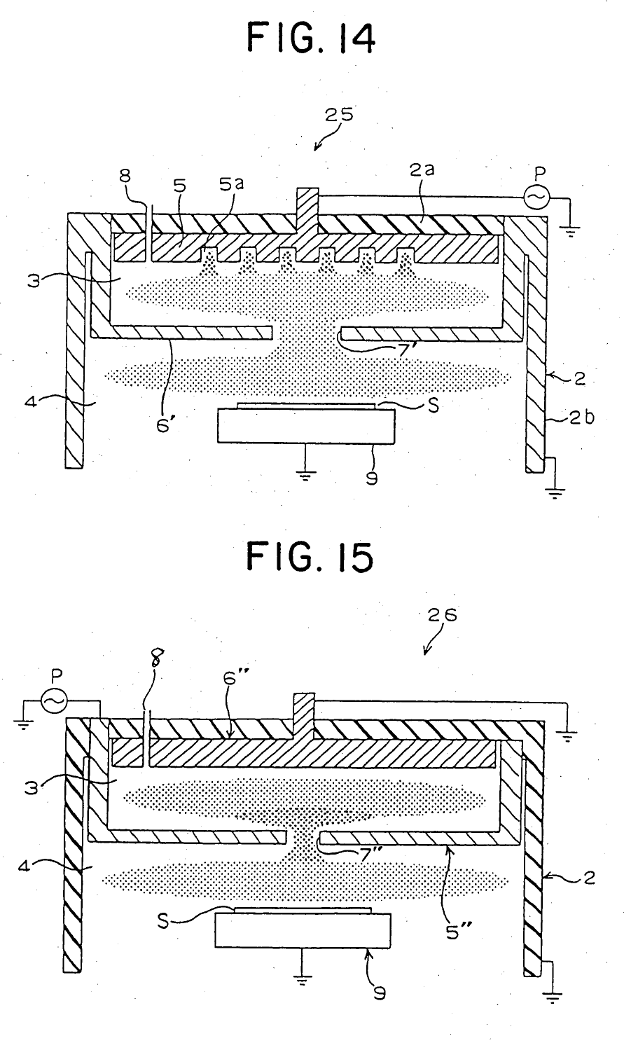

FIG. 14 is a schematic view of a surface treatment apparatus 25 according to a seventh embodiment of the present invention. In this surface treatment apparatus 25, the inside of the casing 2 is also divided into two chambers, the plasma generation chamber 3 and the substrate treatment chamber 4. The cathode electrode 5 and an anode electrode 6′ are disposed in the plasma generation chamber 3 and the anode electrode 6′ divides the plasma generation chamber 3 and the substrate treatment chamber 4. A circular plasma nozzle 7′ is formed at the center of the anode electrode 6′, and this plasma nozzle 7′ connects the plasma generation chamber 3 and substrate treatment chamber 4.

For the cathode electrode 5, a plurality of recesses 5a having circular cross section are disposed on the face of the cathode electrode 5 opposed to the anode electrode 6′. The opening width W of this recess 5a is set in a range satisfying either of W≦5L(e) or W≦20X. It is more preferable to set the opening width W in a range satisfying X/5≦W. Hollow cathode discharge is generated at the recess 5a by setting the diameter of the recess 5a in such range.

The aforementioned composition of this embodiment is similar to the first embodiment mentioned above, but it is different from the surface treatment apparatus 1 of the aforementioned first embodiment in that hollow discharge is not generated at the plasma nozzle 7′ because the opening width W of the plasma nozzle 7′ formed at the anode electrode 6′ is large or the length (thickness) T is small.

As hollow discharge is not generated at the plasma nozzle 7′ in this embodiment, the surface treatment speed and quality are somewhat inferior to the aforementioned first embodiment, but its treatment speed and treatment quality is improved, compared to the conventional surface treatment apparatus, because hollow cathode discharge is generated at the recess 5a of cathode electrode 5.

FIG. 15 is a schematic view of a surface treatment apparatus 26 according to an eighth embodiment of the present invention. In this surface treatment apparatus 26 also, the inside of the casing 2 is divided into two chambers, the plasma generation chamber 3 and the substrate treatment chamber 4. A cathode electrode 5″ and an anode electrode 6″ are disposed in the plasma generation chamber 3 and the power applied cathode electrode 5″ divides the plasma generation chamber 3 and the substrate treatment chamber 4. A circular plasma nozzle 7″ is formed at the center of the cathode electrode 5″, and this plasma nozzle 7″ connects the plasma generation chamber 3 and the substrate treatment chamber 4.

As the opening width W of the plasma nozzle 7″ is set in a range satisfying either of W≦5L(e) or W≦20X, hollow cathode discharge is generated at the plasma nozzle 7″. In other words, the plasma nozzle 7″ of this embodiment corresponds to the hollow discharge area of the first aspect of this invention and at the same time, corresponds to the hollow cathode discharge area of the second aspect of this invention.

Though the plasma generation chamber 3 is disposed above the surface treatment apparatus and the substrate treatment chamber 4 is disposed thereunder in any of the aforementioned embodiment, contrarily to these embodiments, the apparatus may be so composed to flow plasma from under to upward by arranging the plasma generation chamber 3 under, and the substrate treatment chamber 4 thereabove. Further, the casing of the surface treatment apparatus may be divided into right and left chambers, and the plasma generation chamber and the substrate treatment chamber may be disposed horizontally, to compose an apparatus in which plasma flows in the traversal direction. In any case, the substrate can by disposed in opposition to the plasma nozzle and orthogonal to the plasma flow direction or the substrate can be disposed parallel to the plasma flow direction. The plasma generation means is also not limited to a pair of plasma generation electrodes, but includes plasma generation means such as discharge including electrodes of three poles or more, microwave discharge, capacitance coupling type discharge, inductive coupling type discharge, PIG discharge, electron beam excitation discharge.

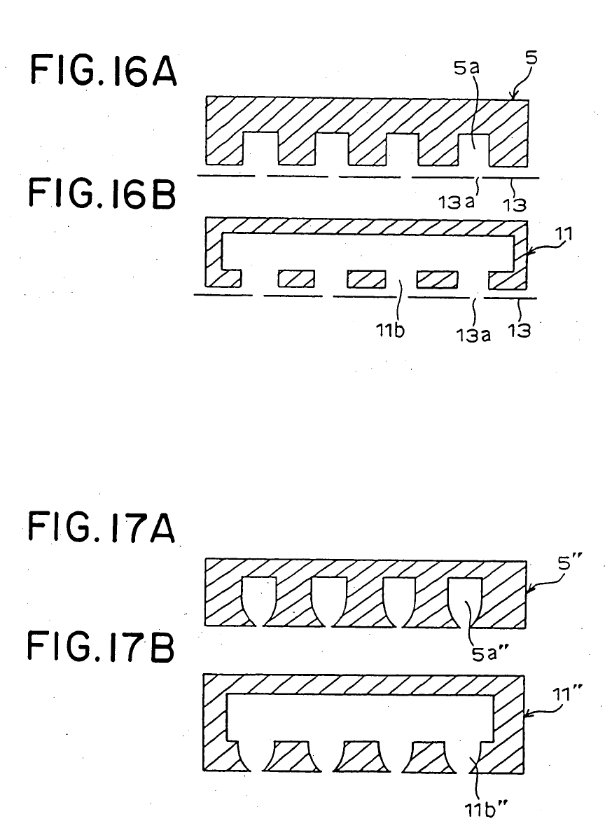

As shown in FIGS. 16A and 16B, another electrode 13 can be disposed in the vicinity of anode side and/or opposite side of the cathode electrodes 5 and 11 where hollow cathode discharge is generated. The another electrode 13 has multiple small holes 13a formed thereon, having an opening width smaller than the opening width W of the recess 5a formed at the cathode 5 or the through hole 11b formed at the cathode electrode 11 which is the hollow element. Otherwise, the another electrode 13 may be mesh shaped. Even in case of cathode electrode having a through hole where hollow cathode discharge is generated, similarly, another electrode 13 provided with multiple small holes smaller than the opening width W of the through hole may be disposed.

The another electrode 13 is biased to an arbitrary voltage including floating state, and it is particularly preferable that it is set to a voltage value between the grounded anode electrode 6 and the maximum value of the plasma space potential, or it is set to a voltage value between the voltage of the cathode electrode 5 where hollow cathode discharge is generated and the maximum value of the plasma space potential.

Moreover, much electrons will be defined in the hollow cathode discharge area and an ultra high density hollow cathode discharge, which is a discharge of much more electric current, becomes possible by forming the small holes 13a formed on the another electrode 13 at a position corresponding to the recess 5a or through hole 11b of the cathode electrodes 5 and 11 as shown in FIGS. 16A and 16B.

Alternatively, electrons can be entrapped effectively in a recess 5a″, a through hole 11b″, or hollow portion, that are hollow cathode discharge area, by forming the opening portion area sufficiently smaller than the cross section of the other portions of the recess 5a″ or the through hole 11b″, at the recess 5a″ formed on the cathode electrode 5″ or the through hole 11b″ on the cathode electrode 11″, as shown in FIGS. 17A and 17B. Though the recess 5a″ or the through hole 11b″ have its upper half in cylindrical shape and the lower half in hemispherical shape in the drawing, they may be conical, prism-shaped or spindle-shaped.

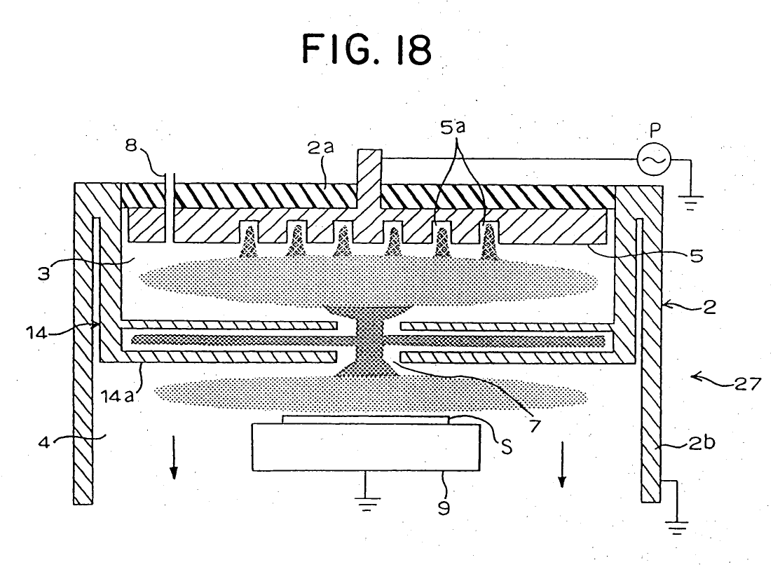

FIG. 18 is a schematic view of a surface treatment apparatus 27 according to a ninth embodiment of the present invention. This apparatus 27 is substantially identical to the surface treatment apparatus 1 of the aforementioned first embodiment except that the portion of an anode electrode 14 opposed to the cathode electrode 5 is a hollow element.

The portion of the anode electrode 14 opposed to the cathode electrode 5 is a hollow element 14a, and a single plasma nozzle 7 passing through an upper wall section 14b and a lower wall section 14c in a straight line is formed at the center of this hollow element 14a. Moreover, in this embodiment, in order to make the inside of the hollow element 14a of the anode electrode 14 the hollow cathode discharge generation area, the distance between opposed face along the formation direction of the plasma nozzle 7 of the hollow element 14a, namely the height H which is vertical in the drawing, is set in a range satisfying either of H≦5L(e) or H≦20X. L(e) is an electron mean free path in respect to atom or molecular species (active species) of the smallest diameter among raw material gas species and electrically neutral atom or molecular species (active species) produced therefrom by decomposition, under the desired plasma generation conditions, and X is a thickness of a sheath layer generated under the desired plasma generation conditions. It is preferable to set the hollow inside height H in a range satisfying X/20≦H, and it is preferable to set the height further in a range satisfying X/5≦H.

In this embodiment, in addition to the hollow anode discharge at the plasma nozzle 7 and hollow cathode discharge at the recess 5a of the cathode electrode 5, hollow anode discharge is generated inside of the hollow element 14a of the anode electrode 14, and new plasma is generated also in the hollow element 14a of the anode electrode 14. Therefore, the density of process plasma attaining the substrate S increases further, active species contributing to the film formation treatment increases, improving the surface treatment speed, and further its treatment quality.

Though, in the drawing, the inner height H of the hollow element 14a is constant, the height H does not have to be constant. It is preferable to reduce the inner height H of the hollow element in the vicinity of the center, increasing gradually its height H in the outer peripheral direction, or increase the inner height H of the hollow element in the vicinity of the center, reducing gradually its height H in the outer peripheral direction according to the applied power frequency or other condition, to uniform hollow anode discharge substantially in the whole area of the hollow element 14a.

It is not necessary that hollow anode discharge is generated in the whole inside of the hollow element 14a, but the surface treatment quality and treatment speed improvement can be observed only if hollow anode discharge is generated at least in a portion thereof.

FIG. 19 is a modification of the aforementioned anode electrode 14 which is a hollow element. Though the single plasma nozzle 7 was formed through the center of the hollow element 14a in the aforementioned anode electrode 14, a plurality of through holes 14d may be formed as plasma nozzle, communicating respectively with the hollow inside, on the upper wall section 14b and the lower wall section 14c of the hollow element 14a. In this case, it is preferable not to align vertically in the straight line the through holes 14d of the upper wall section 14b and the through holes 14d of lower wall section 14c but to offset them. Moreover, it is preferable to form the through holes 14d in the disposition of FIG. 33A to FIG. 36B.

The opening width W of the plurality of through holes 14d do not have to be the same for all of them, but can be set to different opening width W conveniently to uniform hollow anode discharge for the plurality of through holes 14d. Particularly, it is preferable to reduce the opening width W of the through hole 14d in the vicinity of the center, increasing gradually its opening width W in the outer peripheral direction, or increase the opening width W in the vicinity of the center, reducing gradually its opening width W in the outer peripheral direction according to the applied power frequency or other condition.

The approximate lower limit of the length T of the through hole 14d, namely the thickness T of the lower wall section 14b for this embodiment is X/50. The upper limit is decided by the apparatus dimensional restriction. The length T of this trough hole 14d is preferably 0.1 to 70 mm for the aforementioned gas pressure and diameter.

Though the through hole 14d has a circular cross section in this embodiment, it can also has an oval, rectangular, polygonal, undefined form or other arbitrary form. The cross section is not necessarily constant, and the cross section may change in the axial direction. Moreover, the trough hole 14d may be a slit structure having a rectangular cross section, or a slit structure having a two-dimensional extension such as whorl form or meandering form. When such slit structure is adopted, the opening width W of this through hole 14d corresponds to the slit width and this slit width is set within the aforementioned range. Also, a partial relief may be formed on the inner wall face of the through hole 14d. It is unnecessary to make the plurality of the through holes 14d identical each other in dimensions or shape, and a plurality of through holes 14d having different dimensions and shape may be formed.

On the anode electrode 14′, a gas inlet 8′ can be formed at a position opening at the inner wall section of the through hole 14d or inside the hollow element 14a. For example, in case of film formation treatment, only carrier gas may be introduced in the plasma generation chamber 3 and the gas inlet 8′ of the anode electrode 14′ may introduce raw material gas such as monosilane or the like, to prevent raw material gas from decomposing in the unnecessary space and to make raw material gas contribute effectively to the film formation treatment. In addition, a plurality of through holes 14d may all be provided with the gas inlet 8′, or only certain through holes 14d may be provided with the gas inlet 8′. Moreover, a plurality of gas inlets 8′ may open on the inner wall surface of the hollow element 14a.

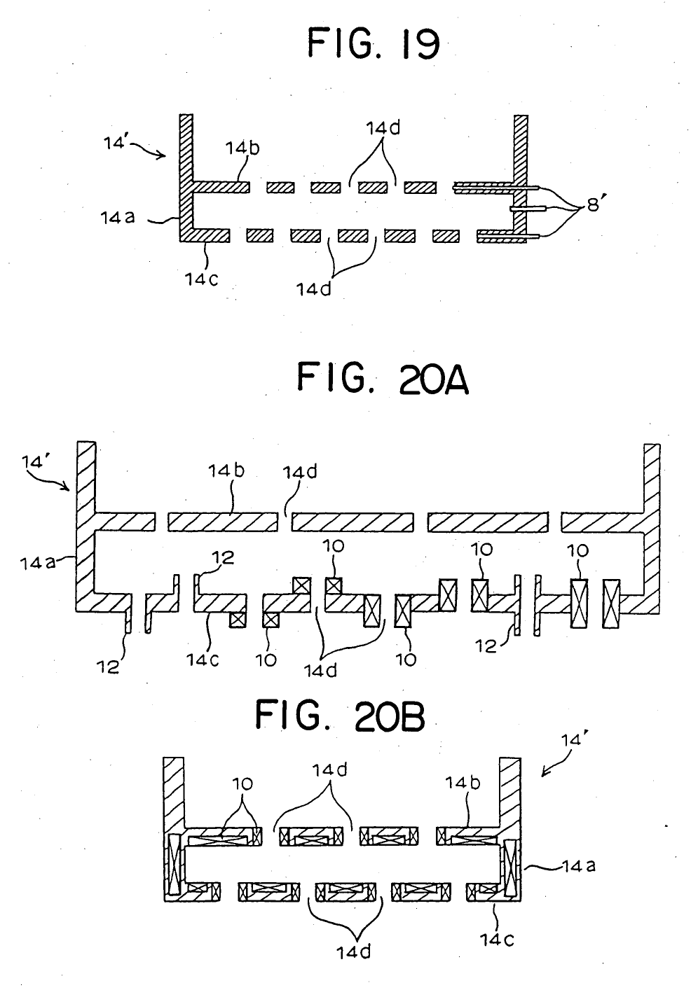

FIGS. 20A and 20B show modifications wherein the density of plasma generated by hollow anode discharge inside the hollow element 14a and the through holes 14d in the anode electrode 14′ is increased.

First, from the view point of effective generation of hollow anode discharge in the through hole 14d, it is preferable to enlarge the length T of the through hole 14d, to generate stronger plasma. However, the thickness of the upper and lower wall sections 14b and 14c of the anode electrode is preferably minimum for resisting the gas pressure introduced into the hollow inside and the applied electricity, from the viewpoint of material cost.

Therefore, in order to increase the length T of the through hole 14d, it is preferable to attach the nozzle element 12 at the periphery of the through hole 14d of the lower wall section 14c. This nozzle element 12 may protrude from the through hole 14d to the substrate treatment chamber 4 side, or protrude into the hollow element 14a. It may also protrude to both side. The same nozzle element 12 may also be composed of magnet 10 as shown in FIG. 20A. At this moment, it is preferable that the magnet 10 is not exposed directly to plasma.

Though all nozzle elements 12 shown in FIG. 20A are disposed aligning its central line with the line of the through hole 14d, the center line of the nozzle element 12 and the axial line of the through hole 14d may make a certain angle, namely, the nozzle element 12 may be disposed slant. Though the nozzle element 12 shown in FIG. 20A is a cylinder having a constant cross section, the shape is not limited to this, but it may be a cylinder having a shape gradually increasing or reducing its cross section. Moreover, tubular nozzle elements can be disposed in spiral.

Moreover, in order to increase the surface area of the anode electrode 14′ in contact with plasma, the inside of the hollow element 14a of the anode electrode 14′ may by partitioned into a plurality of chambers by partition walls extending vertically, or horizontally. The through holes 14d formed in each chamber of the divided inside may all be identical, or may be different. Besides, the partition walls extending vertically may have gaps between the walls and the upper and lower wall sections 14b and 14c of the hollow element 14a, and respective chambers may be connected with each other.

It is also possible to embed the magnet 10, as shown in FIG. 20B, in inner circumferential surface of respective through hole 14d, the upper and lower wall sections 14b and 14c of the anode electrode 14a or the peripheral wall section, or in the vicinity thereof so as to impart a magnetic filed to the inside of the through hole 14d, plasma nozzle, or hollow element 14a. It is preferable to dispose the magnet 10 so that magnetic lines of flux become parallel with the axial direction of the through hole 14d or so that magnetic lines of flux become parallel with the upper and lower wall sections 14b and 14c.

Such magnetic field formation at the through hole 14d and hollow element 14a allows electrons to remain for a long time in the through hole 14d and hollow element 14a by adjusting the orbit of electrons in the plasma generated therein. Such electron obit adjustment accelerates the generation of active species and improves the surface treatment speed, as the electron acting time to the raw material gas is extended without increasing the electron energy (electron temperature).

FIGS. 21 to FIG. 23 are schematic views of surface treatment apparatuses 28 to 30 according to the first to third modifications of the aforementioned ninth embodiment. The substrate treatment apparatus 28 shown in FIG. 21 is the one wherein the cathode electrode 5 of the ninth embodiment is replaced by the cathode electrode 11 of the hollow element, and the hollow inside of the cathode electrode 11 and the through hole 11b formed in the cathode electrode 11 are used as hollow cathode discharge area.

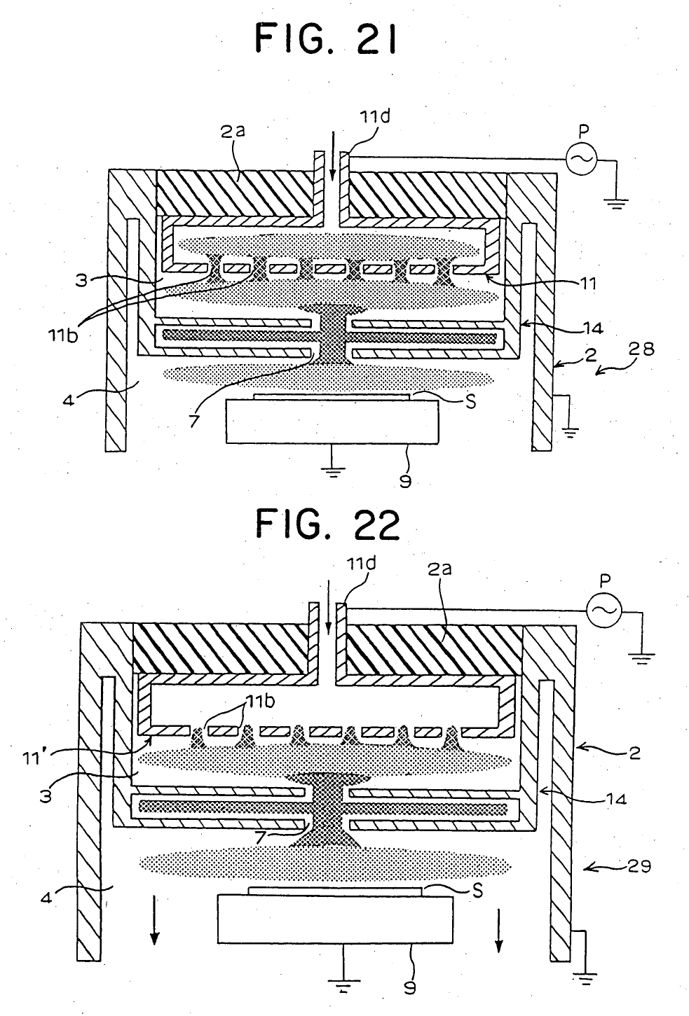

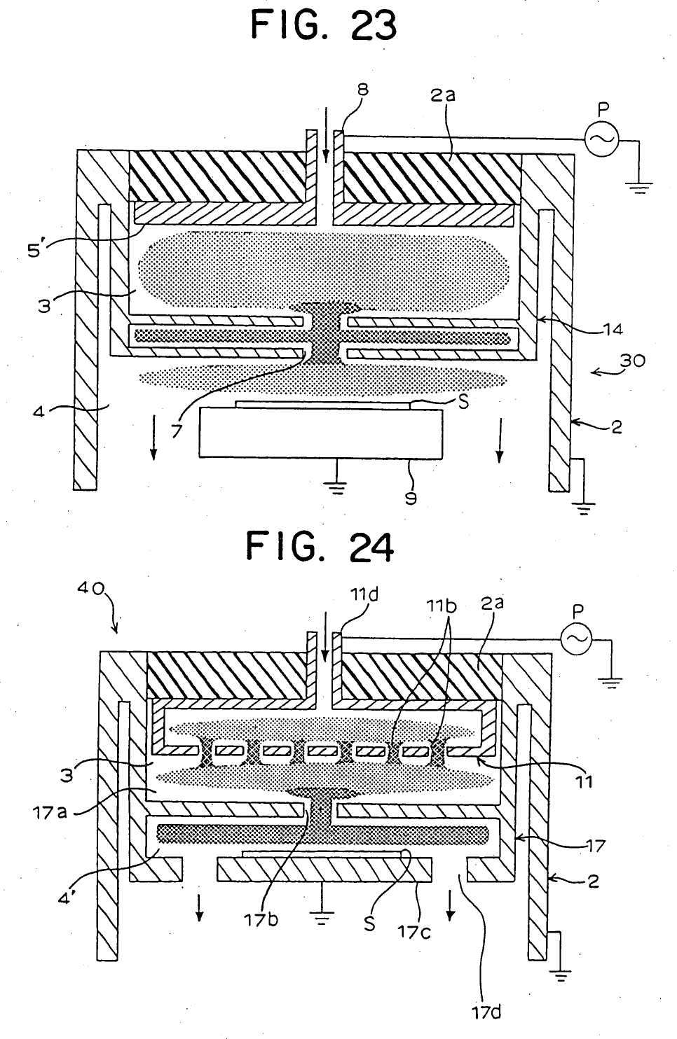

The surface treatment apparatus 29 shown in FIG. 22 is the one wherein the cathode electrode 5 of the ninth embodiment is replaced by the cathode electrode 11′ comprising a hollow element whose inner wall surface is insulated, and the through hole 11b formed in the cathode electrode 11′ is used as hollow cathode discharge area. Besides, the surface treatment apparatus 30 shown in FIG. 23 is the one wherein the cathode electrode 5 of the ninth embodiment is replaced by a simple flat plate shaped electrode 5′, and hollow cathode discharge is not generated by the cathode electrode 5′, and only hollow anode discharge is generated.

All of these modifications are combinations of the ninth embodiment and the aforementioned other embodiment of the present invention, and each of them are provided with functions and effects of respective embodiments mentioned above. Therefore, in any of these modifications, the process plasma density is increased and the treatment is accelerated considerably by hollow anode discharge or hollow cathode discharge.

FIG. 24 is a schematic view of a surface treatment apparatus 40 according to a tenth embodiment of the present invention. In this surface treatment apparatus 40, the inside of a hollow anode electrode 17 constitutes a substrate treatment chamber 4′.

The hollow anode electrode 17 is provided with a through hole 17b formed at the center of an upper wall section 17a, and this through hole 17b constitutes the plasma nozzle. Besides, the inner surface central portion of the lower wall portion 17c of the anode electrode 17 constitutes the substrate support table, and at the same time, a plurality of exhaust outlets 17d are formed at the periphery portion of the lower wall portion 17c. The central portion of the lower wall portion 17c may include a substrate heating means. Note that the substrate support position in the anode electrode 17 and the exhaust outlet 17d formation position are not limited to those mentioned above, but an arbitrary position can be selected.

In this embodiment, in order to make the through hole 17b of the anode electrode 17 the hollow anode discharge generation area, the opening width W of the through hole 17b is set in a range satisfying either of W≦5L(e) or W≦20X. It is preferable to set the opening width W in a range satisfying X/20≦W, and it is preferable to set the opening width W further in a range satisfying also X/5≦W. Also, in this embodiment, in order to make the hollow inside of the anode electrode 17 also the hollow anode discharge generation area, the height H of the hollow inside is set in a range satisfying either of H≦5L(e) or H≦20X. It is also preferable to set the height H of the hollow inside in a range satisfying X/20≦H, and it is preferable to set the height H further in a range satisfying also X/5≦H.

However, L(e) is an electron mean free path in respect to atom or molecular species (active species) of the smallest diameter among raw material gas species and electrically neutral atom or molecular species (active species) produced therefrom by decomposition, under the desired plasma generation conditions, and X is a thickness of a sheath layer generated under the desired plasma generation conditions.

In the surface treatment apparatus 40, as the substrate treatment chamber 4′ is formed in the hollow inside of the anode electrode 17, and hollow anode discharge is generated in this hollow inside of the anode electrode 17, the density of plasma contributing to the treatment of the substrate S increases extremely, improving the surface treatment speed remarkably. However, as ion damage to the substrate S by plasma is considerable, this surface treatment apparatus 40 is not appropriate for the film formation treatment, but the apparatus 40 is appropriate to etching, ashing or ion doping treatment.

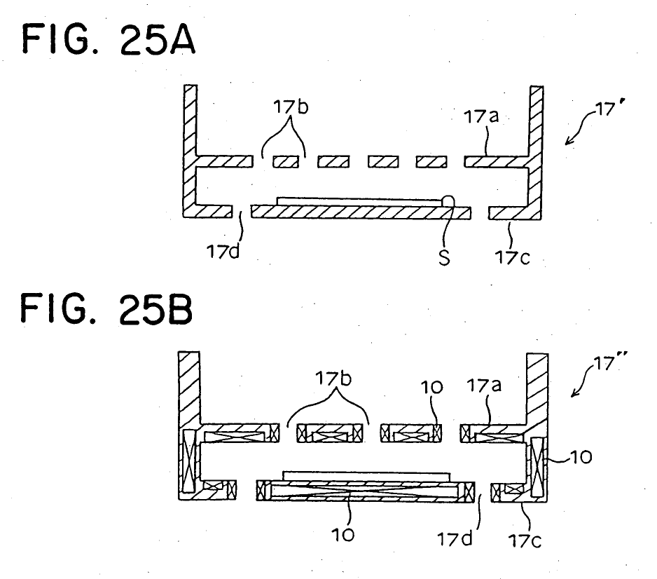

FIGS. 25A and 25B are modifications of the hollow anode electrode composing the substrate treatment chamber 4′. The anode electrode 17′ shown in FIG. 25A is different from the aforementioned anode electrode 17 in that the plurality of through holes 17b composing the plasma nozzle are formed in the upper wall section 17a. The through holes 17b are preferably formed in the disposition as shown in FIG. 33A to FIG. 36B.

Though the plurality of through holes 17b have a circular cross section in this embodiment, they can also has an oval, rectangular, polygonal, undefined form or other arbitrary form. The cross section is not necessarily constant, and the cross section may change in the axial direction. Moreover, the trough hole 17b may be a slit structure having a rectangular cross section, or a slit structure having a two-dimensional extension such as whorl form or meandering form. When such slit structure is adopted, the opening width W of this through hole 17b corresponds to the slit width and this slit width is set within the aforementioned range. Also, a partial relief may be formed on the inner wall face of the through hole 17b. It is unnecessary to make a plurality of the through holes 17b identical each other in dimensions or shape, and a plurality of through holes 17b having different dimensions and shapes may be formed.

It is also possible to embed the magnet, as shown in FIG. 25B, in inner circumferential surface of respective through hole 17b and the exhaust outlet 17d, the upper and lower wall sections 17a and 17c in the hollow inside of the anode electrode 17n or the peripheral wall section thereof, or in the vicinity thereof so as to impart a magnetic filed to the inside of the through hole 17b, exhaust outlet 17d, hollow inside. It is preferable to arrange the magnet 10 so that magnetic lines of flux become parallel with the axial direction of the through hole 17b or exhaust outlet 17d, or so that magnetic lines of flux become parallel with the upper and lower wall sections 17a and 17d.

Such magnetic field formation at the through hole 17b and hollow inside allows electrons to remain for a long time in the through hole 17b and hollow inside by adjusting the orbit of electrons in the plasma generated therein. Such electron obit adjustment accelerates the generation of active species and improves the surface treatment speed, as the electron acting time to the raw material gas is extended without increasing the electron energy (electron temperature).

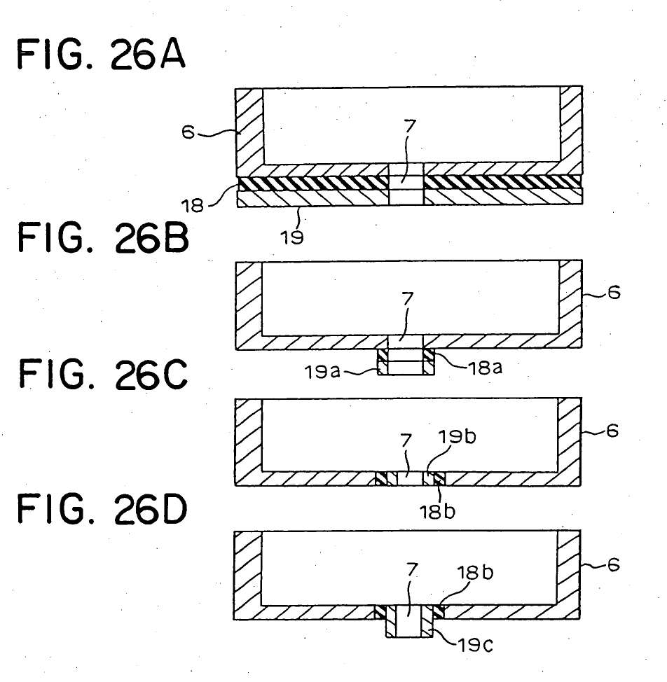

FIGS. 26A to 26D show modifications to facilitate the hollow discharge in various through holes. FIGS. 26A to 26D illustrate the plasma nozzle 7 formed at the anode electrode 6 as example.

In a modification shown FIG. 26A, a plate shaped insulator 18 is disposed in close contact with the bottom surface of the anode electrode 6, and another electrode 19 made of metal plate is disposed on the bottom surface of the insulator 18. The plasma nozzle 7 is formed passing through the anode electrode 6, insulator 18 and another electrode 19. DC bias or AC bias (including high frequency or pulse) are applied to this another electrode 19 so that its potential will be lower than the potential of the anode electrode.

The plasma potential is determined by the potential of an electrode in contact with most of this plasma, that is, in this case, the potential of the anode electrode 6. Compared to the area of this anode electrode 6, the contact area with plasma of the plasma nozzle 7 is extremely small, but the differential voltage between the plasma potential and the plasma nozzle can be controlled at will by applying bias to this plasma nozzle 7. Therefore, even in case of low poer discharge with which ordinarily the differential voltage between the plasma potential and the anode electrode 6 is small and the low power discharge can not generate hollow plasma at the plasma nozzle 7, the differential voltage between the plasma and the plasma nozzle 7 can be increased by applying bias to the another electrode 19, hollow plasma discharge can be induced at the plasma nozzle 7.

As for another disposition example of the another electrode for setting the plasma nozzle 7 potential at will, in addition, as shown in FIG. 26B, an annular insulator 18a and an annular another electrode 19a can be disposed overlapped only at the bottom face of the formation portion of the plasma nozzle 7 in the anode electrode 6.

As shown in FIG. 26C, an annular another electrode 19b may be disposed on the inner wall surface of the plasma nozzle 7 in the anode electrode 6 via an annular insulator 18b, or, as shown in FIG. 26D, a cylindrical nozzle shaped another electrode 19c may be disposed on the inner wall surface of the plasma nozzle 7 in the anode electrode 6 via the annular insulator 18b.

Such structure can be applied similarly to the case where a plurality of through holes are formed on the anode electrode, or various through holes such as through holes formed through the cathode electrode.

Though, in the aforementioned various embodiments and modifications, a high frequency power by a high frequency power supply P is input to the plasma generation electrode, DC voltage may be applied by a DC power supply. Or, bias may be applied respectively by a DC or AC power supply, or by a pulse power supply.

Moreover, it is also possible to compose in the triode type by installing mesh shaped electrodes between the substrate S placed in the surface treatment chamber 4 and the plasma nozzle 7, and to apply various bias.

Though the inside of the casing 2 of the surface treatment apparatus is vertically divided into two chambers, the plasma generation chamber 3 above and the substrate treatment chamber 4 under, by an anode electrode 6 in every embodiment mentioned above, the present invention is not limited to such apparatus.

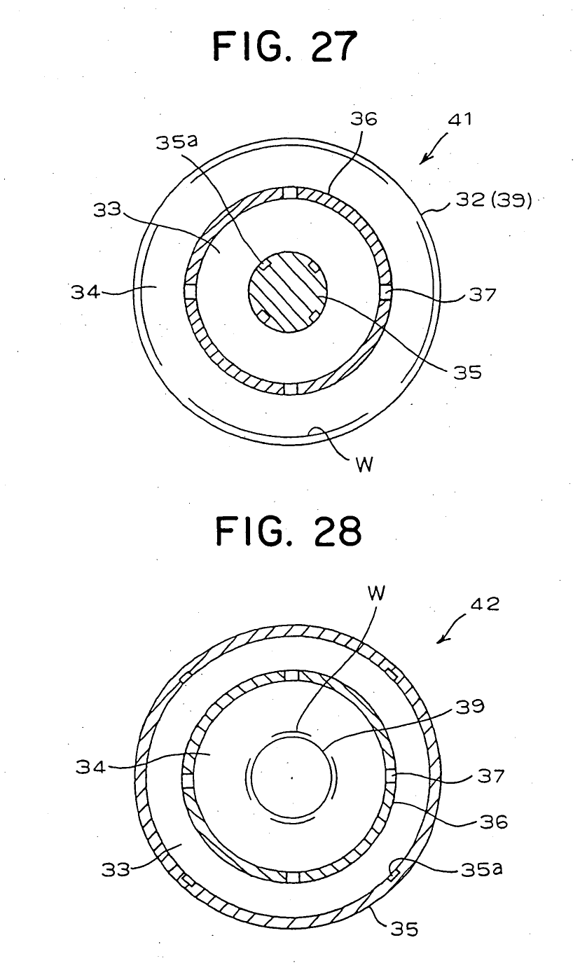

FIG. 27 to FIG. 32 are horizontal cross sections of a surface treatment apparatus according to other embodiments of the present invention.

In a surface treatment apparatus 41 according to an eleventh embodiment of the present invention shown in FIG. 27, a casing 32 is composed of a bottomed cylinder, and the peripheral wall inner surface is used as the substrate support table 9. In this case, a cathode electrode 35 composed of small diameter cylinder and an anode electrode 36 composed of a cylinder whose diameter is larger than the cathode electrode 35 are disposed in the casing 32 aligning their central axes.

A plurality of plasma nozzles 37 having a predetermined shape and disposition are formed at the anode electrode 36, the area between the anode electrode 36 and the casing 32 composes a substrate treatment chamber 34 of the present invention, and the area between the cathode electrode 35 and the anode electrode 36 composes a plasma generation chamber 33 of the present invention. Further, a plurality of recesses 35a parallel to the axial direction are formed on the peripheral wall face of the cathode electrode 35 with a predetermined phase difference. Moreover, When the cathode electrode 35 is a hollow element, a through hole may be formed in place of the recess 35a, and its hollow inside may be supplied with carrier gas and raw material gas.

Alternatively, as a surface treatment apparatus 42 of a twelfth embodiment of the present invention shown in FIG. 28, the maximum diameter cylinder can be set as cathode electrode 35 and the anode electrode 36 made of a cylinder may be disposed therein aligning their axes, and further a smallest diameter cylinder 39 may be disposed at the center thereof. In this case, the outer circumferential surface of the central cylinder 39 composes a support table for the substrate W. A plurality of the recesses 35a parallel to the axial direction are formed on the inner circumference surface of the cathode electrode 35 with a predetermined phase difference. A plurality of the plasma nozzles 37 having a predetermined shape and disposition are formed at the anode electrode 36. Further, the casing may be disposed further outside of the cathode electrode 35.

In the eleventh and twelfth embodiments shown in FIGS. 27 and 28 also, hollow anode discharge is generated at the plasma nozzle 37 by setting the opening width of the nozzle within the range prescribed by the present invention. Also, hollow cathode discharge is generated at the recess 35a, by setting the opening width of the recess 35a within the range prescribed by the present invention.

Further, by forming a hollow element by the anode element 35 and cathode electrode 36 and forming a through hole at the opposed surface of respective electrode, hollow discharge can be generated at this through hole, and moreover, hollow discharge can be generated in at least a part of the hollow inside. In this case, plasma contributing to the surface treatment becomes more dense, improving the surface treatment speed.

Such apparatus wherein the anode electrode 35 and cathode electrode 36 are made of cylinder, is useful for applying surface treatment to the cylindrical substrate such as photosensitive dram. Alternatively, it is preferable, in roll-to-roll continuous film formation, etching or other surface treatment is applied to a substrate made of band shaped film member, taking profit of the curbed surface of a part of the cylinder because space required for the apparatus can be reduced.

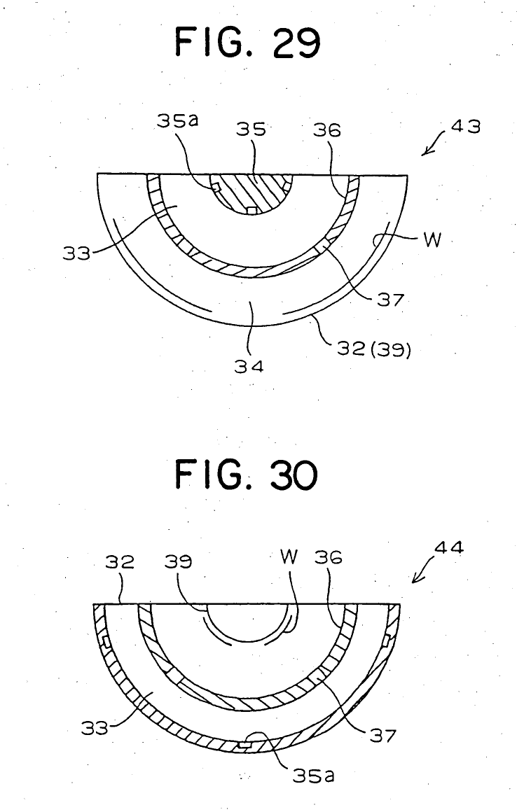

Respective plasma generation electrode may be spherical and have a cross section form as shown in the aforementioned FIGS. 27 and 28. Or, respective plasma generation electrodes 35 and 36 may be formed so that its cross section is a part of curbed surface such as semicircular cylinder or hemisphere like as surface treatment apparatuses 43 and 44 according to thirteenth and fourteenth embodiments of the present invention shown in FIGS. 29 and 30. Thus, by making the plasma generation electrode spherical, hemispherical or partially curbed surface, an uniform surface treatment can be applied to special form substrates such as spherical semiconductor.

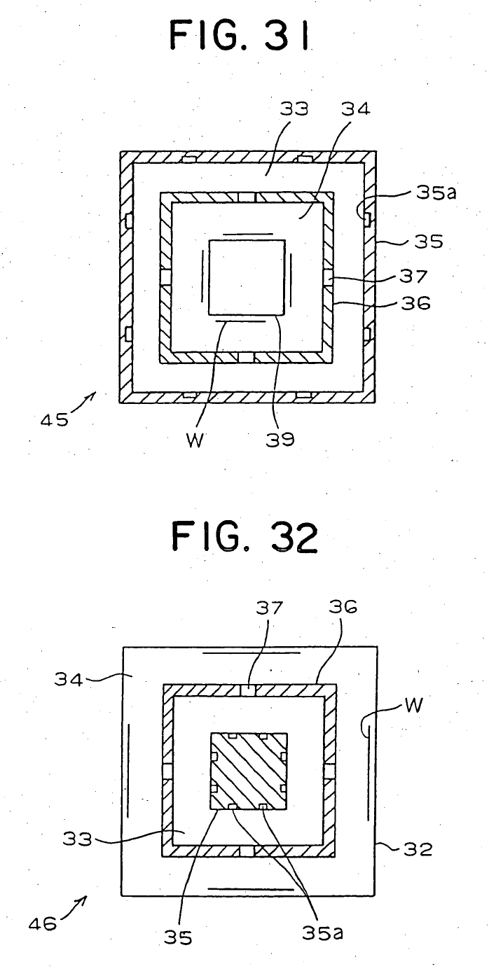

Moreover, in surface treatment apparatuses 45 and 46 according to fifteenth and sixteenth embodiments of the present invention shown in FIGS. 31 and 32, plasma generation electrodes 35 and 36 may be a cylinder having a square cross section. Or they may be have a cylinder shape with polygonal cross section or polyhedron shape. By making the plasma generation electrodes 35 and 36 prism shaped, the apparatus space can be reduced. Further, by composing these plasma generation electrodes 35 and 36 of various shape by a hollow element, and forming a through hole at the opposed surface of respective electrodes, hollow discharge can be generated at this through hole, and moreover, hollow discharge can be generated in at least a part of the hollow inside and plasma can become more dense.

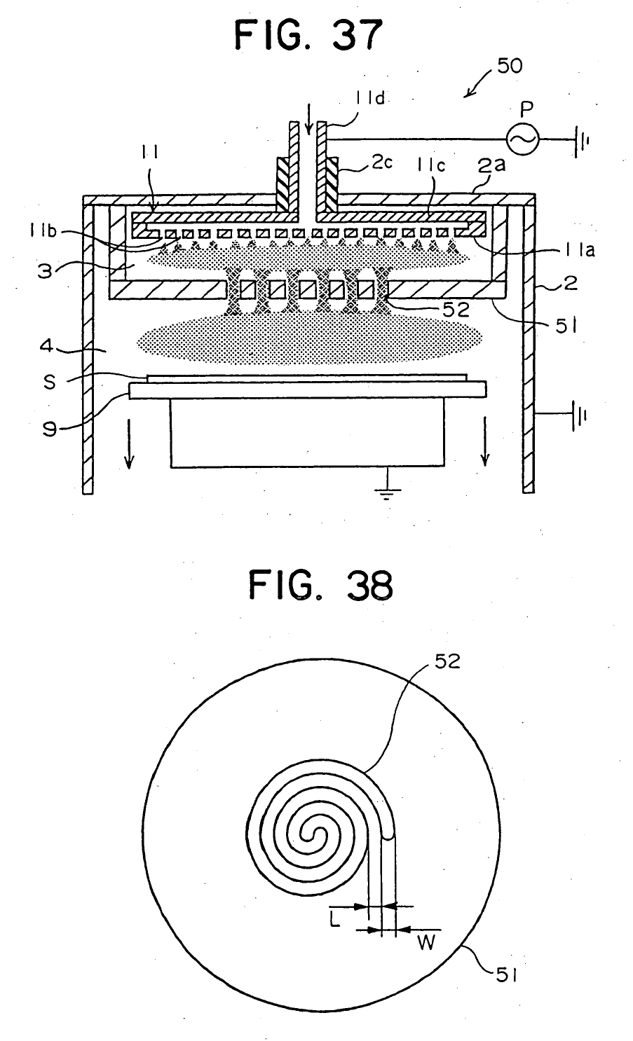

FIGS. 37 and 38 show a surface treatment apparatus 50 according to a seventeenth embodiment of the present invention. In this embodiment, the same reference numerals will be given to the composition identical with those in the aforementioned embodiment, and detailed description thereof will be omitted.

A pair of plasma generation electrodes 11 and 51 are disposed in parallel vertically in the plasma generation chamber 3. The upper electrode (cathode electrode) 11, connected to a high frequency power supply P, of the pair of electrodes 11 and 51 is attached to the upper wall 2a of the casing 2 via an insulator 2c, while the grounded lower electrode (anode electrode) 26 separates the plasma generation chamber 3 and the substrate treatment chamber 4. The anode electrode 51 is attached to the upper wall 2a of the grounded casing 2, but it is not limited to this, and it can be attached to any position of the casing 2.

A slit shaped plasma nozzle 52 having a whorl shaped top surface as shown in FIG. 38 is formed at the center of the anode electrode 51, and the plasma generation chamber 3 and the substrate treatment chamber 4 are connected each other through this plasma nozzle 52. Here, separately from the anode electrode 51, a partition plate to define the plasma generation chamber 3 and substrate treatment chamber 4 can be disposed and a plasma nozzle can be formed on the partition plate.

In this embodiment, it is important that the plasma nozzle 52 is whorl shaped, namely, formed in an elongated substantially continuous slit shape that can be drawn with a single stroke of the brush. Moreover, the slit width W of this plasma nozzle 52 is longitudinally uniform, and the whorl interval L is made equal to the slit width W. Preferably, the slit width W is set in a range satisfying either of W≦5L(e) or W≦20X, and it is more preferable to set in a range satisfying X/5≦W. L(e) is an electron mean free path in respect to atom or molecular species (active species) of the smallest diameter among raw material gas species and electrically neutral atom or molecular species (active species) produced therefrom by decomposition, under the desired plasma generation conditions, and X is a thickness of a sheath layer generated under the desired plasma generation conditions.

In this seventeenth embodiment, hollow anode glow discharge is induced in the whorl shaped plasma nozzle 52. As for plasma induction in the whorl shaped formed in an elongated substantially continuous slit shape that can be drawn with a single stroke of the brush, it is believed that hollow anode glow discharge is induced at an arbitrary position inside the plasma nozzle 52, and hollow anode glow discharge is propagated in the whole inside of the plasma nozzle 52 by chain reaction.

The density of plasma introduced in the substrate treatment chamber 4 is increased, because hollow anode glow discharge is induced in the plasma nozzle 52. Moreover, in this embodiment, the plasma nozzle 52 is formed substantially over a wide range of the anode electrode 51, by shaping the plasma nozzle 52 in a whorl form, and further, substantially uniform surface treatment can be realized over a wide range of the substrate S, because plasma is spouted out from the total length of the plasma nozzle 52.

In this embodiment, the generation of hollow anode glow discharge at the plasma nozzle 52 is further accelerated, because the plasma nozzle 52 slit width W is set in a range satisfying either of W/5≦5L(e) or W/5≦20X.

Moreover, because the electron energy in the plasma generated in the plasma generation chamber 3 is reduced conveniently to an intensity sufficient for generating active species and insufficient for generating ions when it passes through the plasma nozzle 52 which is the hollow anode discharge generation area, plasma introduced into the substrate treatment chamber 4 further increases in species contributing to the film formation, increases in its density, so as to increase the film formation speed remarkably. Still further, as the ion energy in the plasma also drops when it passes through the plasma nozzle 7 where the hollow anode glow discharge is being generated, the plasma introduced into the substrate treatment chamber 4 contains less ions damaging the substrate by collision therewith, so as to enable a high quality film formation.

Now the effect of the invention according to the seventeenth embodiment will be described with Examples and comparing with comparative examples.

### EXAMPLE 1

In the surface treatment apparatus 50, when the silicone thin film formation treatment was realized with anode 51 of thickness 7.0 mm, slit width W 8.0 mm of the whorl shaped plasma nozzle 52 formed on the anode electrode 51, and whorl interval L 8.0 mm, the obtained silicone film was crystallized even when the film treatment speed was increased. The slit width used for the film formation treatment satisfies the hollow discharge induction conditions.

### COMPARATIVE EXAMPLE

When the silicone thin film formation treatment was performed similarly to the Example 1 using an anode of 7.0 mm in thickness, wherein a single circular plasma nozzle of 50 mm in diameter is formed at the center, in place of the anode 51 of the surface treatment apparatus 50, the obtained silicone film was amorphous when the film treatment speed was increased, and crystalline silicone film could not be obtained. The orifice diameter used for this film formation treatment does not satisfy the hollow discharge induction conditions.

TABLE 2

| | | Comparative |
|---|---|---|
| | Example 1 | example |
| Plasma nozzle shape | Whorl slit shape | Circular |
| | Slit width W: 8.0 mm | Diameter: 5.0 mm |
| | Whorl interval L: 8.0 mm | |
| Anode electrode | 7.0 mm | 7.0 mm |
| thickness | | |
| Slit width conditions | Satisfied | Not satisfied |
| W ≦ (e) or W ≦ 20X | | |
| Film formation speed | 6.0 Å/sec | 5.0 Å/sec |
| Film nature | Crystalline | Amorphous |

Though, in the aforementioned seventeenth embodiment, the anode electrode 51 is grounded, however bias may be applied respectively on the electrodes 11 and 51 by a DC or AC power supply, or by a pulse power supply. Though the plasma generation chamber 3 and the substrate treatment chamber 4 are defined by the anode electrode 51 in the embodiment mentioned above, a partition plate to define the plasma generation chamber 3 and substrate treatment chamber 4 can be disposed, separately from the anode electrode 51.

When ashing, etching or other surface treatment are performed using the aforementioned surface treatment apparatus, the surface treatment can be performed at a temperature lower and speed higher than before.

Now, a preferred modification of the plasma nozzle which is a characteristic portion of the present invention will be described.

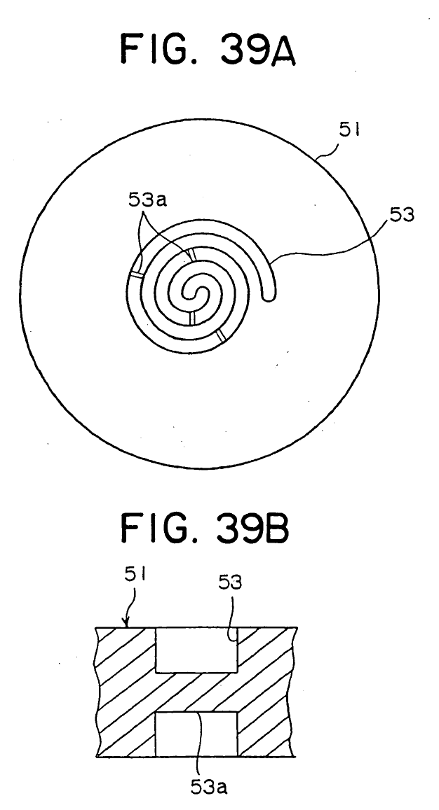

Similarly to the aforementioned plasma nozzle 52, a plasma nozzle 53 shown in FIGS. 39A and 39B also has an whorl shaped top face, ribs 53a for connecting the slit width at a plurality of points are formed. The form of the plasma nozzle 53 can be held stably by forming the rib 53 at a plurality of points, even when the partition plate (anode electrode 51) wherein, for example, the plasma nozzle 53 is formed, is thin.

For the formation of such rib 53a, it is important that the plasma nozzle 53 is substantially continuous. Namely, it is important not to divide plasma generated in the plasma nozzle 53, by reducing the thickness direction dimensions of the rib 53a to be smaller than the plate thickness, or reducing the width dimension of the rib 53a.

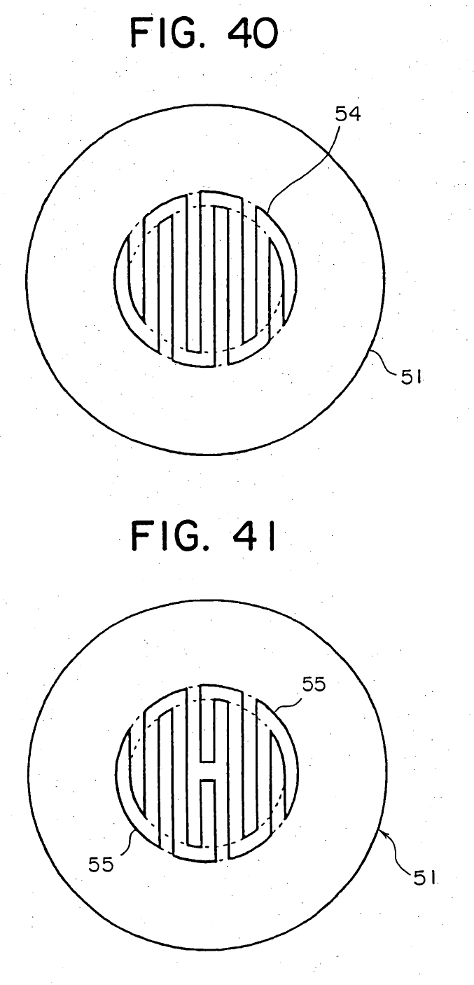

A plasma nozzle 54 shown in FIG. 40 has a zigzag meandering shaped top surface. This plasma nozzle 54 is point symmetric in respect to the center of the partition plate (anode electrode 51).

A plasma nozzles 55, 55 shown in FIG. 41 have also a zigzag meandering shaped top surface. This is the shape of the plasma nozzle 54 shown in the aforementioned FIG. 40 and is divided at the central portion of the partition plate (anode electrode 51). The two plasma nozzles 55, 55 are formed point symmetrically in respect to the center of the partition plate (anode electrode 51).

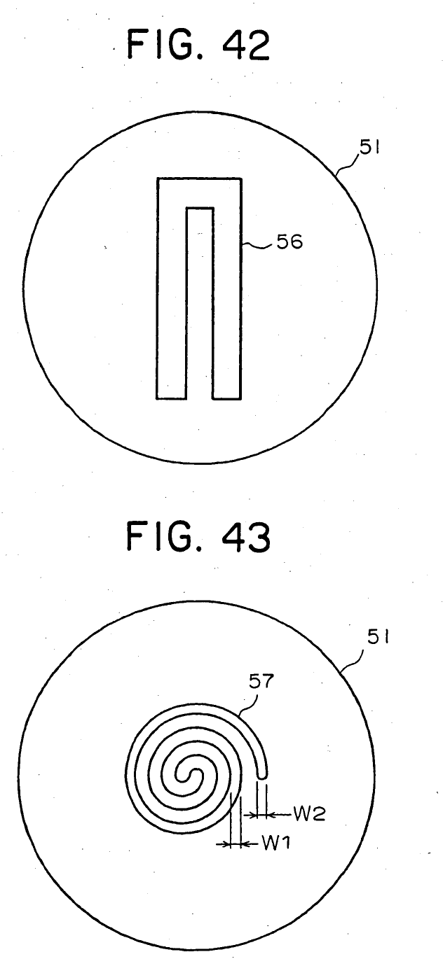

A plasma nozzle 56 shown in FIG. 42 has a substantially U-formed top surface connecting straight lines. Moreover, the open end section can be connected for rectangular shape, and liked with a rib mentioned above, so that the central portion may not drop.

A plasma nozzle 57 shown in FIG. 43 has a zigzag meandering shaped top surface, and further, its slit width W is reduced gradually from a slit width W1 in the vicinity of the center of the partition plate (anode nozzle 51) towards the outer periphery slit width W2. In this modification, for example, when plasma is generated by applying high frequency power supply whose frequency is 13.56 MHz, if the slit width W of the whorl shaped plasma nozzle 52 is made constant, as in the surface treatment apparatus 50 shown in the aforementioned FIGS. 37 and 38, plasma attaining the substrate S tends to be weak at the central portion, and becomes stronger towards an outer circumferential portion. When the plasma density is uneven as in this case, the density of plasma eventually attaining the substrate S surface can be uniformed by gradually reducing the slit width W from the vicinity of the center of the partition plate toward the outer circumference as shown in FIG. 43, and a stable film thickness distribution and film quality can be obtained at a high film formation speed.

### EXAMPLE 2

The plasma nozzle 57 shown in FIG. 43 is adopted for silicone thin film formation treatment as in Example 1, be setting the slit width W1 in the vicinity of the center of the partition plate to 8.0 mm, the slit width W2 in the vicinity of the outer circumference to 6.0 mm, and the whorl interval D to 8.0 mm. As a result, crystalline silicone thin film was obtained, and its film thickness distribution was more uniformed than Example 1.

TABLE 3

| | Example 1 | Example 2 |
|---|---|---|
| Plasma nozzle | Whorl slit shape | Whorl slit shape |
| shape | Slit width W: Constant | Slit width W: Variable |
| | 8.0 mm | W1 8.0 mm |
| | Whorl interval L: 8.0 mm | W2 6.0 mm |
| | | Whorl interval L: 8.0 mm |
| Anode | 7.0 mm | 7.0 mm |
| electrode | | |
| thickness | | |
| Film thickness | 0.75 | 1.00 |
| distribution | | |
| (uniformity)* | | |
| Film nature | Crystalline | Crystalline |

*The film thickness distribution is normalized by dividing the thinnest portion of the formed film by the thickest portion.

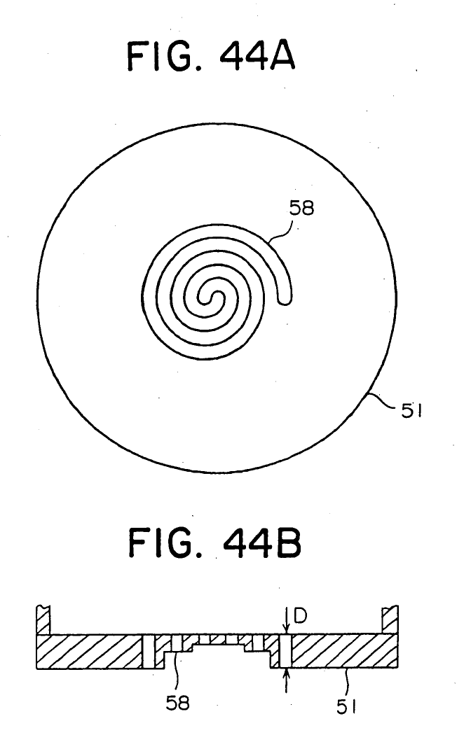

A plasma nozzle 58 shown in FIGS. 44A and 44B has a whorl shaped top surface and a constant slit width W, further, its slit depth D, namely partition plate (anode nozzle 51) thickness dimension increases gradually from the center towards the outer periphery. As the plasma nozzle 58 shown in FIGS. 44A and 44B, the density of plasma eventually attaining the substrate S surface can be uniformed by gradually increasing the slit depth D from the vicinity of the center of the partition plate toward the outer circumference, and a stable film thickness distribution and film quality can be obtained at a high film formation speed.

As for the plasma nozzle 57 shown in the aforementioned FIG. 43, its slit width W is reduced gradually from the center of the anode electrode 51 where the plasma nozzle 57 is formed towards the outer periphery, while the slit depth D of plasma nozzle 58 shown in FIGS. 44A and 44B increases gradually from the center towards the outer periphery slit width W2. This is a measure against an tendency that, when plasma is generated by applying high frequency power supply whose frequency is 13.56 MHz as mentioned above, plasma density attaining the substrate S tends to be weak at the central portion, and becomes stronger towards the outer circumferential portion.

However, when the frequency is multiplied nearly by 8, for example about 100 MHz, contrary to the aforementioned tendency, it is observed that the plasma density tends to decreases from the center to the outer periphery. In such a case, it is preferable to increase the plasma nozzle slit width W from the center toward the outer periphery, or to reduce the slit depth D from the center toward the outer periphery. Anyway, the slit width and slit depth of the plasma nozzle is to be set conveniently in view of the plasma density attaining the substrate S according to various plasma generation conditions such as applied power frequency, chamber pressure, temperature or others.

1. A surface treatment apparatus for making raw material gas plasma by generating plasma, in a casing provided with plasma generation means, a raw material gas inlet and a substrate support table, by the plasma generation means and giving plasma treatment to the surface of a substrate placed on the substrate support table, wherein:
said casing is defined into two chambers, a plasma generation chamber provided with said plasma generation means and a substrate treatment chamber provided with said substrate support table;
said substrate treatment chamber and said plasma generation chamber are connected through one or more plasma nozzles;
at least one of said plasma nozzles is made a hollow discharge generation area; and
a hollow plasma generation electrode comprising one or more hollow discharge generation areas is disposed in said plasma generation chamber.

2. A surface treatment apparatus according to claim 1, wherein an opening width W(1) of the smallest portion on at least one of the plasma nozzles is set in a range satisfying either of W(1)≦5L(e) or W(1)≦20X:
where L(e) is an electron mean free path in respect to atom or molecular species (active species) of the smallest diameter among raw material gas species and electrically neutral atom or molecular species (active species) produced there from by decomposition, under the desired plasma generation conditions; and
X is a thickness of a sheath layer generated under the desired plasma generation conditions.

3. A surface treatment apparatus according to claim 1, wherein said plasma nozzle forms a substantially continuous and elongated slit shape that can be drawn with a single stroke of the brush.

4. A surface treatment apparatus according to claim 3, wherein said plasma nozzle is whorl shaped.

5. A surface treatment apparatus according to claim 3, wherein said plasma nozzle is meandering shaped.

6. A surface treatment apparatus according to claim 3, wherein said plasma nozzle is connected straight lines shaped.

7. A surface treatment apparatus according to claim 3, wherein said plasma nozzle is formed symmetrically in respect with its center.

8. A surface treatment apparatus according to claim 3, wherein a slit width W of the plasma nozzle is set in a range satisfying either of W≦5L(e) or W≦20X:
where L(e) is an electron mean free path in respect to atom or molecular species (active species) of the smallest diameter among raw material gas species and electrically neutral atom or molecular species (active species) produced therefrom by decomposition, under the desired plasma generation conditions; and
X is a thickness of a sheath layer generated under the desired plasma generation conditions.

9. A surface treatment apparatus according to claim 3, wherein said plasma nozzle varies its slit width from a center to an outer circumference thereof.

10. A surface treatment apparatus according to claim 3, wherein said plasma nozzle varies its slit depth from a center to an outer circumference thereof.

11. A surface treatment apparatus according to claim 1, wherein said hollow plasma generation electrode includes one or more recesses on a surface opposed to plasma generated by the plasma generation means and, at least one of the recesses is made the hollow discharge generation area.

12. A surface treatment apparatus according to claim 1, wherein said hollow plasma generation electrode is a hollow body, said electrode includes one or more through holes communicating with a hollow inside on a portion opposed to plasma generated by the plasma generation means and, at least one of said through holes is made the hollow discharge generation area.

13. A surface treatment apparatus according to claim 11, wherein an opening width W(2) of the smallest portion of the recess or the through hole is set in a range satisfying either of W(2)≦5L(e) or W(2)≦20X:
where L(e) is an electron mean free path in respect to atom or molecular species (active species) of the smallest diameter among raw material gas species and electrically neutral atom or molecular species (active species) produced therefrom by decomposition, under the desired plasma generation conditions; and
X is a thickness of a sheath layer generated under the desired plasma generation conditions.

14. A surface treatment apparatus according to claim 12, wherein an opening width W(2) of the smallest portion of the recess or the through hole is set in a range satisfying either of W(2)≦5L(e) or W(2)≦20X:
where L(e) is an electron mean free path in respect to atom or molecular species (active species) of the smallest diameter among raw material gas species and electrically neutral atom or molecular species (active species) produced therefrom by decomposition, under the desired plasma generation conditions; and
X is a thickness of a sheath layer generated under the desired plasma generation conditions.

15. A surface treatment apparatus according to claim 1, wherein said hollow plasma generation electrode is a hollow body, said electrode includes one or more through holes communicating with a hollow inside on a portion opposed to plasma generated by the plasma generation means and, a hollow discharge generation area is made in at least a portion of the hollow inside.

16. A surface treatment apparatus according to claim 12, wherein said hollow plasma generation electrode is a hollow body, said electrode includes one or more through holes communicating with a hollow inside on a portion opposed to plasma generated by the plasma generation means and, a hollow discharge generation area is made in at least a portion of the hollow inside.

17. A surface treatment apparatus according to claim 15, wherein an opposed face distance H in the hollow inside along the formation direction of said through hole of the hollow plasma generation electrode is set in a range satisfying either of H≦5L(e) or H≦20X:
where L(e) is an electron mean free path in respect to atom or molecular species (active species) of the smallest diameter among raw material gas species and electrically neutral atom or molecular species (active species) produced therefrom by decomposition, under the desired plasma generation conditions; and
X is a thickness of a sheath layer generated under the desired plasma generation conditions.

18. A surface treatment apparatus according to claim 1, wherein a magnetic field is formed in the vicinity of said plasma nozzle and/or in the vicinity of said recess, through hole, and/or in the hollow inside.

19. A surface treatment apparatus according to claim 1, wherein said apparatus comprises potential applying means for applying a desired potential to the substrate.
